(19) United States
(12) Patent Application Publication
(10) Pub. No.: US 2024/0308202 A1
(43) Pub. Date: Sep. 19, 2024

(54) WATERLESS PLANOGRAPHIC PRINTING ORIGINAL PLATE, METHOD FOR PRODUCING WATERLESS PLANOGRAPHIC PRINTING PLATE, METHOD FOR SORTING WATERLESS PLANOGRAPHIC PRINTING PLATE, AND METHOD FOR PRODUCING PRINTED MATERIAL

(71) Applicant: TORAY INDUSTRIES, INC., Tokyo (JP)

(72) Inventors: Yasunori KUSE, Otsu-shi (JP); Yuki KASE, Otsu-shi (JP); Takejiro INOUE, Otsu-shi (JP)

(73) Assignee: TORAY INDUSTRIES, INC., Tokyo (JP)

(21) Appl. No.: 18/573,821

(22) PCT Filed: Aug. 1, 2022
(86) PCT No.: PCT/JP2022/029447

§ 371 Date: Dec. 22, 2023

(30) Foreign Application Priority Data
Aug. 24, 2021 (JP) 2021-136047

(51) Int. Cl. B41C 1/10; B41M 5/025; B41N 1/00; G03F 7/105

(52) U.S. Cl. CPC B41C 1/1016; B41M 5/025; B41N 1/003; G03F 7/105; B41C 2210/02; B41C 2210/16; B41C 2210/22

(57) ABSTRACT

Disclosed is a waterless planographic printing plate precursor including at least a substrate, a heat sensitive layer and an ink repellent layer in this order, wherein the substrate has a white color layer or a white color surface, and wherein the heat sensitive layer includes at least (a) an infrared-absorbing dye having a maximum absorption wavelength of 700 to 1,000 nm, (b) a dye that changes color by proton acceptance, and (c) a proton-donating compound. The present invention provides a waterless planographic printing plate precursor capable of obtaining high contrast between the image area and the non-image area by exposure without the need for a special layer.

### TECHNICAL FIELD

The present invention relates to a waterless planographic printing plate precursor, a method for producing a waterless planographic printing plate using the same and a sorting method, and a method for producing a printed material.

### BACKGROUND ART

Examples of the printing method using a planographic printing plate include printing with water in which a thin layer of water containing chemicals (hereinafter referred to as “dampening solution”) is formed on the surface of the planographic printing plate in advance during printing to form non-image areas that repel ink, and waterless printing in which an ink repellent layer such as a silicone rubber layer is formed instead of dampening solution to form non-image areas that repel ink.

In printing with water, since dampening solution continues to be supplied during printing, waste liquid mixed with dampening solution and an ink, whereas waterless printing is a printing method with less environmental load because no dampening solution is used.

A waterless planographic printing plate used for waterless printing has conventionally been fabricated by a plate-making process including the steps of exposing a waterless planographic printing plate precursor (exposure step), immersing the exposed waterless planographic printing plate precursor in chemicals to swell and dissolve the surface of a heat sensitive layer and/or a photosensitive layer of the exposed area (pre-treatment step), rubbing the surface to remove an ink repellent layer of the image area (development step), and dyeing the image area with a solution containing dye to enhance the visibility (dyeing step).

With the increase in environmental awareness in recent years, chemical-free printing is also progressing in the printing industry, and it is also required to use no chemicals in the plate-making process for waterless planographic printing plate. In response to this problems, there have been proposed, as technologies capable of obtaining planographic printing plates with satisfactory bakeout properties and proofing properties during chemical-free development, a directly imageable waterless planographic printing plate precursor comprising at least a heat sensitive layer and an ink repellent layer in this order on a substrate, wherein the heat sensitive layer is composed of a composition containing a mixture of at least a dye that changes color by the action of an acid, and an acid (see, for example, Patent Document 1); and a planographic printing plate precursor comprising at least a heat sensitive layer containing an infrared-absorbing compound and an ink repellent layer in this order on a substrate, characterized by having a colored layer, which does not contain an infrared-absorbing compound but contains a dye compound, between the heat sensitive layer and the ink repellent layer (see, for example, Patent Document 2).

### PRIOR ART DOCUMENTS

### Patent Documents

Patent Document 1: JP 2001-51409

Patent Document 2: JP 2020-26136

### SUMMARY OF THE INVENTION

### Problems to be Solved by the Invention

Although the contrast between the image area and the non-image area can be increased by the directly imageable waterless planographic printing plate precursor mentioned in Patent Document 1, it is required that the image area and the non-image area have higher contrast with an increase in speed of the printing step and plate-making process in recent years. In particular, when an image pattern is discriminated by a machine, a higher contrast is conventionally required. Meanwhile, although the planographic printing plate precursor mentioned in Patent Document 2 is capable of obtaining a high contrast between the image area and the non-image area after exposure, there has been a problem that the productivity decreases due to the formation of the colored layer.

Thus, it is an object of the present invention to provide a waterless planographic printing plate precursor capable of obtaining high contrast between the image area and the non-image area by exposure without the need for a special layer.

### Solutions to the Problems

The present invention is directed to a waterless planographic printing plate precursor having at least a substrate, a heat sensitive layer and an ink repellent layer in this order, wherein the substrate has a white color layer or a white color surface, and wherein the heat sensitive layer comprises at least (a) an infrared-absorbing dye having a maximum absorption wavelength of 700 to 1, 000 nm, (b) a dye that changes color by proton acceptance, and (c) a proton-donating compound.

### Effects of the Invention

According to the present invention, it is possible to obtain a waterless planographic printing plate precursor capable of obtaining high contrast between the image area and the non-image area by exposure without the need for a special layer.

### EMBODIMENTS OF THE INVENTION

The waterless planographic printing plate precursor of the present invention (hereinafter sometimes referred to as “printing plate precursor”) will be described below.

The printing plate precursor of the present invention includes at least a substrate, a heat sensitive layer and an ink repellent layer in this order. The substrate has the function of holding the heat sensitive layer, the ink repellent layer and the like. The heat sensitive layer has the function of generating heat leading to decomposition by irradiation with infrared rays (exposing), thus facilitating the removal of the ink repellent layer at the exposed area. By removing the ink repellent layer, the exposed heat sensitive layer becomes the image area that receives the ink. That is, the exposed area becomes the image area. Since the ink repellent layer has the function of repelling the printing ink, the non-exposed area from which the ink repellent layer is not removed becomes a non-image area. Thus, an image pattern is formed by the exposed area (image area) and the non-exposed area (non-image area).

A first aspect of the present invention is characterized by combining a substrate having a white color layer or a white color surface with a heat sensitive layer containing at least (a) an infrared-absorbing dye having a maximum absorption wavelength of 700 to 1,000 nm (hereinafter sometimes referred to as “infrared-absorbing dye (a)”), (b) a dye that changes color by proton acceptance (hereinafter sometimes referred to as “dye (b)”) and (c) a proton-donating compound. The heat sensitive layer of the printing plate precursor according to the first aspect of the present invention is in a colored state due to the coexistence of the dye (b) and the proton-donating compound (c). In such heat sensitive layer, infrared-absorbing dye (a) generated heat by exposure, and the thus generated heat causes loss of the interaction between the dye (b) and the proton-donating compound (c), resulting in fading as well as partial thermal decomposition and gasification of the layer. By having a substrate having a white color layer or a white color surface under the heat sensitive layer, the color of the faded heat sensitive layer of the exposed area overlaps with the white color of the substrate, and the color of the image area (exposed area) of the printing plate base plate observed from the ink repellent layer side becomes a whitish color. Meanwhile, when the white color layer or white color surface of the substrate overlaps with the color of the heat sensitive layer of the unexposed area, the brightness of the non-image area (non-exposed area) is improved. Therefore, the contrast between the exposed and non-exposed area can be increased.

Subsequently, the substrate and each layer will be described.

### Substrate

It is possible to use, as the substrate, those with little dimensional change in the printing process, which are conventionally used as the substrate for printing plates. Examples thereof include substrates made of paper, metal, glass, plastic material and the like. More specifically, examples thereof include papers; papers laminated with plastics (polyethylene, polypropylene, polystyrene, etc.); metal plates of aluminum (including aluminum alloys), zinc and copper; glass plates of soda lime glass and quart; silicon wafers; films of plastics such as cellulose acetate, polyethylene terephthalate, polyethylene, polyester, polyamide, polyimide, polystyrene, polypropylene, polycarbonate and polyvinyl acetal; and papers or plastic films laminated or deposited with the metals.

Of these substrates, an aluminum plate is particularly preferable because of its little dimensional change in the printing process. In quick printing applications, a polyethylene terephthalate film is particularly preferred because of its excellent flexibility.

There is no particular limitation on the thickness of the substrate, and an appropriate thickness suitable for the printing machine to be used for planographic printing may be selected.

These substrates have a white layer or a white color surface to improve the contrast between the image area and the non-image areas, as mentioned above.

Herein, white refers to the reflectance of 50% or more in the full wavelength range when the reflectance is measured under the conditions of a spectral range of 450 to 700 nm and a spectral interval of 10 nm. Such reflectance can be measured by a spectrophotometer (e.g. reflectance graph mode manufactured by “eXact” Advance manufactured by X-Rite, Inc.) for the white layer or white color surface side of a substrate having a white color layer or a white color surface.

The fact that the substrate has a white color layer, means that at least one side of the substrate has a white color layer having a reflectance in the above range. The fact that the substrate has a white color surface means that at least one side of the substrate has a reflectance in the above range. From the viewpoint of further improving the contrast between the image area and the non-image area, the reflectance of the substrate is preferably 70% or more, and still more preferably 75% or more.

Examples of the method of providing a white color layer on the substrate includes a method in which an organic layer composition liquid containing a dye dispersed therein is coated on a substate, a method in which a white film or a sheet is bonded to a substrate, and the like.

Examples of the pigment contained in the white color layer include inorganic white pigments such as titanium oxide, zinc oxide and lithopone; and inorganic yellow pigments such as yellow lead, cadmium yellow, yellow iron oxide, ocher and titanium yellow. Two or more of thereof may be used. Of these, titanium oxide is preferable in terms of coloring power. The particle surface of the pigment may be treated with a titanate-based coupling agent or the like. Such surface treatment can improve the dispersibility of pigment particles and improve the dispersion stability even in the case of high content of pigment particles in the organic layer composition liquid.

When the white color layer contains titanium oxide, the content is preferably from 2% by volume or more and 30% by volume or less in the white color layer. When the content of titanium oxide is 2% by volume or more, the reflectance can be easily increased to 50% or more in the full wavelength range of 450 to 700 nm. Meanwhile, when the content of titanium oxide is 30% by volume or less, the coating performance of the organic layer composition liquid can be improved.

The white color layer may contain an active hydrogen group-containing compound and can improve the adhesion to the substrate and/or the heat sensitive layer. Examples of the active hydrogen group-containing compound include a hydroxyl group-containing compound, an amino group-containing compound, a carboxyl group-containing compound, a thiol group-containing compound and the like. Two or more thereof may be contained. Of these, a hydroxyl group-containing compound is preferable. Examples of the hydroxyl-containing compound include a phenolic hydroxyl group-containing compound, an alcoholic hydroxyl group-containing compound and the like. Examples of the phenolic hydroxyl group-containing compound include a novolac resin, a resole resin and the like. Examples of the alcoholic hydroxyl group-containing compound include epoxy acrylate, epoxy methacrylate, a polyvinyl butyral resin, an epoxy resin and the like. In addition to these compounds, it is possible to exemplify polymers having a hydroxyl group introduced by a known method and the like. Of these active hydrogen group-containing compounds, an epoxy resin is preferably used in terms of the adhesion to the substrate.

Examples of the method of providing a white color surface on the substrate include a method in which the substrate is subjected to a roughening treatment to physically impart fine unevenness or the like.

### Heat Sensitive Layer

The heat sensitive layer of the present invention contains at least (a) an infrared-absorbing dye having a maximum absorption wavelength of 700 to 1,000 nm (infrared-absorbing dye (a)), (b) a dye that changes color by proton acceptance (dye (b)), and (c) a proton-donating compound.

Examples of the infrared-absorbing dye having a maximum absorption wavelength in a range of 700 nm to 1,000 nm (a) include cyanine-based dyes, azulenium-based dyes, squarylium-based dyes, croconium-based dyes, azo-based disperse dyes, bisazostilbene-based dyes, naphthoquinone-based dyes, anthraquinone-based dyes, perylene-based dyes, phthalocyanine-based dyes, naphthalocyanine metal complex-based dyes, polymethine-based dyes, dithiol-nickel complex-based dyes, indoaniline metal complex dyes, intramolecular type CT dyes, benzothiopyran-based spiropyran, nigrosine dyes and the like. Two or more thereof may be contained. By containing two or more infrared-absorbing dyes having different absorption wavelengths can correspond to two or more lasers having different emission wavelengths.

Here, regarding the maximum absorption wavelength of the infrared-absorbing dye (a), wavelength scanning measurement was performed using an ultraviolet-visible near-infrared spectrophotometer under the conditions of a wavelength range of 400 to 1,100 nm and a sampling interval of 5 nm, the wavelength is defined as a wavelength exhibiting a maximum absorbance in the resulting absorption spectrum.

Of these dyes, those having a large molar absorption coefficient ε are preferably used. Specifically, ε is preferably 1×10⁴ L (mol·cm) or more, and more preferably 1×10⁵ L (mol·cm) or more. When ε is 1×10⁴ L (mol·cm) or more, it is possible to further improve the initial sensitivity. Here, ε is the value for the active energy ray to be irradiated. If the specific wavelength of the active energy ray is shown, attention may be paid to 780 nm, 830 nm or 1,064 nm.

The content of the infrared-absorbing dye (a) is preferably 12% by mass to 20% by mass in the heat sensitive layer. By setting the content of the infrared-absorbing dye (a) at 12% by mass or more, the sensitivity to laser light increases, leading to an improvement in image reproducibility. Furthermore, since the heat sensitive layer can be partially burned away and thinned, the color of the faded heat sensitive layer of the exposed area becomes thinner and the color of the image area becomes closer to white color, thus enabling more improvement in contrast between the image area and the non-image area. The content of the infrared-absorbing dye (a) is more preferably 14% by mass or more. Meanwhile, by setting the content of the infrared-absorbing dye (a) at 20% by mass or less, it is possible to suppress peeling of the ink repellent layer, which causes peeling of the ink repellent layer in the non-image area due to heat leakage to the periphery of the exposed area. The content of the infrared-absorbing dye (a) is more preferably 18% by mass or less.

Examples of the dye (b) include acid-base indicators such as Metanil Yellow, Thymol Blue, 4-phenylazodiphenylamine, Methyl Yellow, Methyl Red and Neutral Red; and leuco dyes such as 3-(N,N-diethylamino)-7-(N,N′-dibenzylamino) fluoran, 1-ethyl-8-[ethyl (p-tolyl) amino]-2,2,4-trimethyl-1,2-dihydro-3′H-spiro[chromeno [2,3-g]quinoline-11, 1′-isobenzofuran]-3′-one, 3,3-bis (p-dimethylaminophenyl)-6-dimethylaminophthalide, 3-[4-(diethylamino)-2-hexyloxyphenyl]-3-(1-ethyl-2-methylindol-3-yl)-4-azaphthalide, 3-(4-diethylamino-2-methylphenyl)-3-(1-ethyl-2-methylindol-3-yl)-4-azaphthalide, 3-[(4-diethylamino)-o-tolyl]-6-(dimethylamino)-3-[(4-dimethylamino) phenyl]phthalide, 3′,6′-bis (diphenylamino) spiro[phthalide-3,9′-xanthene], 9-(N-ethyl-N-isopentylamino)spiro[benzo[a]xanthene-12,3′-phthalide], 2-methyl-6-(N-p-tolyl-N-ethylamino)-fluoran, 6′-(dibutylamino)-2′-bromo-3′-methylspiro[phthalide-3,9′-xanthene], 2′-anilino-6′-(N-ethyl-N-isopentylamino)-3′-methylspiro[phthalide-3,9′-xanthene], 2′-anilino-6′-(N,N-dipentan-1-ylamino)-3′-methyl-3H-spiro[isobenzofuran-1,9′-xanthen]-3-one, 2′-anilino-6′-(dibutylamino)-3′-methylspiro[phthalide-3,9′-xanthene], 2′-anilino-6′-[N-ethyl-N-(4-tolyl)amino]-3′-methyl-3H-spiro[isobenzofuran-1,9′-xanthen]-3-one, 6-(diethylamino)-2-[(3-trifluoromethyl)anilino]xanthene-9-spiro-3′-phthalide, 3, 3-bis[2-(4-dimethylaminophenyl)-2-(4-methoxyphenyl)vinyl]-4,5,6,7-tetrachlorophthalide. Two or more thereof may be contained. Of these, leuco dyes are preferred since chemical structures can change between colorless and colored. The leuco dye become colorless when the interaction with the proton-donating compound (c) is lost due to exposure of the heat sensitive layer, thus enabling more improvement in contrast between the image area and the non-image area.

The maximum absorption wavelength when the dye changes color by proton acceptance is preferably in the range of 500 to 650 nm. Since the infrared-absorbing dye (a) exhibits a light green to greenish color, and if the maximum absorption wavelength when the dye (b) accepts protons is in the range of 500 to 650 nm, the color of the heat sensitive layer turns a purple to bluish color which is complementary color thereof. When the interaction between the dye (b) and the proton-donating compound (c) is lost by exposure, the purple to bluish color caused by the dye (b) fades in the heat sensitive layer, and the light green to greenish color caused by the infrared-absorbing dye (a) remains. Therefore, the exposed area (image area) exhibits a light green to greenish color and the non-exposed area (non-image area) exhibits a purple to bluish color, thus enabling more improvement in contrast between the image area and the non-image area.

Here, regarding the maximum absorption wavelength when the dye (b) accepts protons, wavelength scanning measurement was performed using an ultraviolet-visible near-infrared spectrophotometer under the conditions of a wavelength range of 400 to 1,100 nm and a sampling interval of 5 nm, the wavelength is defined as a wavelength exhibiting a maximum absorbance in the resulting absorption spectrum.

Examples of the dye (b) having a maximum absorption wavelength in the range of 500 to 650 nm when accepting protons include 3,3-bis (p-dimethylaminophenyl)-6-dimethylaminophthalide, 3-[4-(diethylamino)-2-hexyloxyphenyl]-3-(1-ethyl-2-methylindol-3-yl)-4-azaphthalide, 3-(4-diethylamino-2-methylphenyl)-3-(1-ethyl-2-methylindol-3-yl)-4-azaphthalide, 3-[(4-diethylamino)-o-tolyl]-6-(dimethylamino)-3-[(4-dimethylamino)phenyl]phthalide, 3′,6′-bis(diphenylamino)spiro[phthalide-3,9′-xanthene] and the like.

It is also possible to use the dye (b) that exhibits a blackish color when accepting protons. The blackish color of the heat sensitive layer fades due to exposure, and the light green to greening color of the infrared-absorbing dye remains, thus enabling more improvement in contrast between the image area and the non-image area.

Examples of the dye (b) that exhibits a blackish color when accepting protons include 2′-anilino-6′-(N-ethyl-N-isopentylamino)-3′-methylspiro[phthalide-3,9′-xanthene], 2′-anilino-6′-(N,N-dipentan-1-ylamino)-3′-methyl-3H-spiro[isobenzofuran-1,9′-xanthen]-3-one, 2′-anilino-6′-(dibutylamino)-3′-methylspiro[phthalide-3,9′-xanthene], 2′-anilino-6′-[N-ethyl-N-(4-tolyl)amino]-3′-methyl-3H-spiro[isobenzofuran-1,9′-xanthen]-3-one, 6-(diethylamino) -2-[(3-trifluoromethyl)anilino]xanthene-9-spiro-3′-phthalide, 3,3-bis [2-(4-dimethylaminophenyl)-2-(4-methoxyphenyl)vinyl]-4,5,6,7-tetrachlorophthalide and the like.

The content of the dye (b) is preferably 5% to 20% by mass in the heat sensitive layer. The contrast between the image area and the non-image area can be more improved by setting the content of the dye (b) at 5% by mass or more. The content of the dye (b) is more preferably 78 by mass or more. Meanwhile, by setting the content of the dye (b) to 15% by mass or less, it is possible to suppress peeling of the ink repellent layer in which the ink repellent layer of the non-image area is peeled.

Examples of the proton-donating compound (c) include an inorganic acid, an organic acid, a polymer including an active hydrogen-containing structural unit and the like. Two or more thereof may be used.

Examples of the inorganic acid include phosphoric acid, boric acid and the like. Examples of the organic acids include a phenolic hydroxyl group, a carboxy group, a sulfo group and the like. Of these, organic acids having a sulfo group such as toluenesulfonic acid, xylenesulfonic acid, cumenesulfonic acid, dodecylbenzenesulfonic acid and dinonylnaphthalene sulfonic are preferable since they have a strong proton-donating property to the dye (b), thus exerting the effect in a small amount. The content (s) of the inorganic acid and/or the organic acid in the heat sensitive layer is/are preferably 0.01 to 5% by mass, more preferably 0.1 to 2% by mass, and still more preferably 0.5 to 2% by mass.

When the inorganic acid and/or the organic acid is/are used as the proton-donating compound (c), the heat sensitive layer may further contain a polymer having a film-forming ability that includes no active hydrogen-containing structural unit.

Examples of such polymer include a melamine resin and the like. The content of the polymer is preferably 20% by mass or more in the heat sensitive layer, and more preferably 30% by mass or more. The content is preferably 95% by mass or less in the heat sensitive layer, and more preferably 80% by mass or less.

The polymer including an active hydrogen-containing structural unit can be preferably used since it can improve the adhesion between the ink repellent layer and the heat sensitive layer by reaction with the adhesive component in the ink repellent layer as the upper layer to suppress peeling of the ink repellent layer, and also can serve as a binder polymer of the heat sensitive layer.

Examples of the polymer including an active hydrogen-containing structural unit include monomers having a carboxyl group, such as (meth) acrylic acid; (meth) acrylic acid esters having a hydroxyl groups, such as hydroxyethyl (meth) acrylate and 2-hydroxypropyl (meth) acrylate; N-alkyl (meth) acrylamide, (meth) acrylamide; reaction products of amines and glycidyl (meth) acrylate or allyl glycidyl; homopolymers or copolymers of ethylenically unsaturated monomers having active hydrogen, such as p-hydroxystyrene and vinyl alcohol; and polymers including a structural unit having active hydrogen in the main chain, and the like. Here, the copolymer monomer component in the copolymer may be another ethylenically unsaturated monomer having active hydrogen and may be an ethylenically unsaturated monomer that has no active hydrogen. Examples of the polymer including a structural unit having active hydrogen in the main chain include polyurethanes, polyureas, polyamides, epoxy resins, polyalkyleneimines, novolac resins, resole resins, cellulose derivatives and the like. Two or more thereof may be contained.

Of these, polymers having an alcoholic hydroxyl group, a phenolic hydroxyl group or a carboxyl group are preferable, polymers having a phenolic hydroxyl group (homopolymer or copolymer of p-hydroxystyrene, novolac resins, resole resins, etc.) are more preferable, and novolac resins are still more preferable. Examples of the novolac resin include phenolic novolac resins and cresol novolac resins.

The content of the polymer including an active hydrogen-containing structural unit is preferably 20% by mass or more in the heat sensitive layer, and more preferably 30% by mass or more, in that the heat sensitive layer surface is decomposed by heat and development is promoted. In terms of the toughness of the heat sensitive layer, the content is preferably 95% by mass or less in the heat sensitive layer, and more preferably 80% by mass or less.

Polymers with film-forming ability (hereinafter referred to as “other polymers X”) that includes no active hydrogen-containing structural unit may be contained, together with polymers including an active hydrogen-containing structural unit.

Examples of the polymer X include homopolymers or copolymers of (meth) acrylates, such as polymethyl (meth) acrylate and polybutyl (meth) acrylate; homopolymers or copolymers of styrene-based monomers, such as polystyrene and α-methylstyrene; various synthetic rubbers such as isoprene and styrene-butadiene; homopolymers of vinyl ester, such as polyvinyl acetate, or copolymers such as vinyl acetate-vinyl chloride; various fused polymers such as polyester and polycarbonate, and the like. Two or more thereof may be contained.

When containing these other polymers X, the total content thereof is preferably 5% by mass or more in the total solid content of the heat sensitive layer composition solution (i.e. in the heat sensitive layer), and more preferably 10% by mass or more, to improve the coatability of the heat sensitive layer composition solution. To achieve high definition image reproduction, the total content thereof is preferably 50% by mass or less in the total solid content of the heat sensitive layer composition solution, and more preferably 30% by mass or less.

When using, as the proton-donating compound (c), a polymer including an active hydrogen-containing structural unit, it is preferable that the heat sensitive layer further contains a crosslinking agent. Examples of the crosslinking agent include a polyfunctional compound having a plurality of functional groups that have reactivity with active hydrogen of the polymer. Examples thereof include polyfunctional isocyanates, polyfunctional blocked isocyanates, polyfunctional epoxy compounds, polyfunctional (meth) acrylate compounds, polyfunctional aldehydes, polyfunctional mercapto compounds, polyfunctional alkoxysilyl compounds, polyfunctional amine compounds, polyfunctional carboxylic acids, polyfunctional vinyl compounds, polyfunctional diazonium salts, polyfunctional azide compounds, hydrazines, organic complex compounds composed of metals and organic compounds, and the like. Two or more thereof may be contained.

Examples of the organic complex compound include organic complex salts consisting of an organic ligand coordinated with metal, organic-inorganic complex salts consisting of an organic ligand and an inorganic ligand coordinated with metal, and metal alkoxides consisting of a metal and organic molecules covalently bonded via oxygen. Of these organic complex compounds, metal chelate compounds with a ligand containing two or more donor atoms to form a ring containing metallic atoms are preferable in view of stability of the organic complex compound itself and stability of the solution of the heat sensitive layer composition.

Major metals composing an organic complex compound are preferably Al(III), Ti(IV), Mn(II), Mn(III), Fe(II), Fe(III), CO(II), Co(III), Ni(II), Ni(IV), Cu(I), Cu(II), Zn(II), Ge, In, Sn(II), Sn(IV), Zr(IV), and Hf(IV). Al(III) is particularly preferable because it can improve the sensitivity effectively, and Ti(IV) is particularly preferable because it serves effectively to develop resistance to printing inks and ink-washing solvent.

The ligand includes a compound having a coordinating group containing oxygen, nitrogen, sulfur, etc. as a donor atom. Specific examples of the coordinating group include those with oxygen as a donor atom such as —OH (alcohol, enol, and phenol), —COOH (carboxylic acid), >C═O (aldehyde, ketone, quinone), —O— (ether), —COOR (ester with R representing an aliphatic or aromatic hydrocarbon), —N═O (nitroso compound), —NO₂ (nitro compound), >N—O (N-oxide), —SO₃H (sulfonic acid), —PO₃H₂ (phosphorous acid) and the like. Specific examples of the coordinating group include those with nitrogen as a donor atom such as —NH₂ (primary amine, hydrazine), >NH (secondary amine), >N— (tertiary amine), —N═N— (azo compound, heterocyclic compound), ═N—OH (oxime), —NO₂ (nitro compound), —N═O (nitroso compound), >C═N— (Schiff base, heterocyclic compound), >C═NH (aldehyde, ketone imine, enamines), —NCS (isothiocyanate) and the like. Specific examples of the coordinating group include those with sulfur as a donor atom such as —SH (thiol), —S-(thioether), >C═S (thioketone, thioamide), ═S— (heterocyclic compound), —C(═O)—SH, —C(═S)—OH, —C(═S)—SH (thiocarboxylic acid), —SCN (thiocyanate) and the like.

Of these organic complex compounds consisting of the metal and ligand mentioned above, compounds used preferably include complex compounds of metals such as Al(III), Ti(IV), Fe(II), Fe (III), Mn (III), Co(II), Co(III), Ni(II), Ni(IV), Cu(I), Cu(II), Zn (II), Ge, In, Sn(II), Sn(IV), Zr(IV), and Hf(IV) with B-diketones, amines, alcohols, and carboxylic acids. Particularly preferable complex compounds include acetyl acetone complexes, acetoacetic acid ester complexes and the like of Al(III), Fe(II), Fe(III), Ti(IV) and Zr(IV).

Specific examples of these compounds include the following compounds such as:
aluminum tris(acetyl acetonate), aluminum tris(ethyl-acetoacetate), aluminum tris(propyl acetoacetate), aluminum tris(butyl acetoacetate), aluminum tris(hexyl acetoacetate), aluminum tris(nonyl acetoacetate), aluminum tris(hexafluoropentadionate), aluminum tris(2,2,6,6-tetramethyl-3,5-heptane dionate), aluminum bis(ethyl acetoacetate)mono(acetyl acetonate), aluminum bis(acetyl acetonate)mono(ethyl acetoacetate), aluminum bis(propyl acetoacetate)mono(acetyl acetonate), aluminum bis(butyl acetoacetate)mono(acetyl acetonate), aluminum bis(hexyl acetoacetate)mono(acetyl acetonate), aluminum bis(propyl acetoacetate)mono(ethyl acetoacetate), aluminum bis(butyl acetoacetate)mono(ethyl acetoacetate), aluminum bis(hexyl acetoacetate)mono(ethyl acetoacetate), aluminum bis(nonyl acetoacetate)mono(ethyl acetoacetate), aluminum dibutoxide mono(acetyl acetonate), aluminum diisopropoxide mono(acetyl acetonate), aluminum diisopropoxide mono(ethyl acetoacetate), aluminum-s-butoxide bis(ethyl acetoacetate), aluminum di-s-butoxide mono(ethyl acetoacetate), and aluminum diisopropoxide mono(-9-octadecenyl acetoacetate); titanium triisopropoxide mono(allyl acetoacetate), titanium diisopropoxide bis(triethanolamine), titanium di-n-butoxide bis(triethanolamine), titanium diisopropoxide bis(acetyl acetonate), titanium di-n-butoxide bis(acetyl acetonate), titanium diisopropoxide bis(2,2,6,6-tetramethyl-3,5-heptane dionate), titanium diisopropoxide bis(ethyl acetoacetate), titanium di-n-butoxide bis(ethyl acetoacetate), titanium tri-n-butoxide mono(ethyl acetoacetate), titanium triisopropoxide mono(methacryloxyethyl acetoacetate), titanium oxide bis(acetyl acetonate), titanium tetra(2-ethyl-3-hydroxyhexyl oxide), titanium dihydroxybis(lactate), and titanium(ethylene glycolate) bis(dioctyl phosphate); zirconium di-n-butoxide bis(acetyl acetonate), zirconium tetrakis(hexafluoropentane dionate), zirconium tetrakis(trifluoropentane dionate), zirconium tri-n-propoxide mono(methacryloxyethyl acetoacetate), zirconium tetrakis (acetyl acetonate), zirconium tetrakis(2,2,6,6-tetramethyl-3,5-heptane dionate), triglycolate zirconic acid, and trilactate zirconic acid; and iron(III) acetyl acetonate, dibenzoyl methane iron(II), tropolone iron, tris-tropolone iron(III), hinokithiol iron, tris-hinokitiol iron(III), acetoacetate iron(III), iron(III) benzoyl acetonate, iron(III) diphenylpropane dionate, iron(III) tetramethylheptane dionate, and iron(III) trifluoropentane dionate. The heat sensitive layer may contain two or more of these compounds.

The content of the organic complex compound is preferably 0.5% by mass or more and 50% by mass or less in the heat sensitive layer, more preferably 5% by mass or more and 20% by mass or less, and still more preferably 10% by mass or more and 20% by mass or less.

### Ink Repellent Layer

It is possible to preferably use, as the ink repellent layer, a silicone rubber layer, which is a crosslinked product of a polyorganosiloxane.

Examples of the silicone rubber layer includes a layer obtained by applying an addition reaction type silicone rubber layer composition or a condensation reaction type silicone rubber layer composition, a layer obtained by applying and drying a solution of these compositions, and the like.

Preferably, the addition reaction type silicone rubber layer composition contains at least a vinyl group-containing organopolysiloxane, an SiH group-containing compound having a plurality of hydrosilyl groups, and a curing catalyst. The silicone rubber layer composition may further contain a reaction inhibitor.

The vinyl group-containing organopolysiloxane has a structure represented by the following general formula (I) and has a vinyl group in the main chain end or in the main chain. In particular, those having a vinyl group in the main chain end are preferable. Two or more thereof may be contained.

—(SiR¹R²—O—)ₙ— (I)

In the general formula (I), n represents an integer of 2 or more. R¹ and R² each independently represent a saturated or unsaturated hydrocarbon group having 1 to 50 carbon atoms. The hydrocarbon group may be linear or branched or cyclic, and may have an aromatic ring.

In the general formula (I), a methyl group preferably accounts for 50% or more of the total of RI and R2 in terms of the ink repellency of the waterless planographic printing plate. From the viewpoint of the image reproducibility, ink repellency and scratch resistance of the waterless planographic printing plate, the weight-average molecular weight of the vinyl group-containing organopolysiloxane is preferably 20,000 or more and 160,000 or less.

Examples of the SiH group-containing compound include organohydrogenpolysiloxane, an organic polymer having a diorganohydrogensilyl group and the like, and organohydrogenpolysiloxane is preferable. Two or more thereof may be contained.

The organohydrogenpolysiloxane can have a linear, cyclic, branched or network molecular structure. Examples thereof include:
polymethylhydrogensiloxane in which both ends of the molecular chain are blocked with a trimethylsiloxy group, dimethylsiloxane-methylhydrogensiloxane copolymer in which both ends of the molecular chain are blocked with a trimethylsiloxy group, dimethylsiloxane-methyl hydrogen siloxane-methylphenylsiloxane copolymer in which both ends of the molecular chain are blocked with a trimethylsiloxy group, dimethylpolysiloxane in which both ends of the molecular chain are blocked with a dimethylhydrogensiloxy group, dimethylsiloxane-methylphenylsiloxane copolymer in which both ends of the molecular chain are blocked with a dimethylhydrogensiloxy group, and methylphenylpolysiloxane in which both ends of the molecular chain are blocked with a dimethylhydrogensiloxy group.

The SiH group-containing compound is preferably a homopolymer of a siloxane structural unit represented by the following general formula (II) or a copolymer of a siloxane structural unit represented by the general formula

(II) and a siloxane structural unit represented by the general formula (III) in terms of the ink repellency.

—[SiH(CH₃—O—]— (II)

—[Si(CH₃)₂—O—]— (III)

The content ratio of the siloxane structural units represented by the general formula (II) to 100 mol % of the total of the siloxane structural units represented by the general formula (II) and the siloxane structural units represented by the general formula (III) in the SiH group-containing compound, ((II)/((II)+(III)), is preferably 50 mol % or more, in terms of large amount of reactable functional groups per one molecule, and excellent reaction rate and curability.

Examples of the reaction inhibitor include nitrogen-containing compounds, phosphorus-based compounds, unsaturated alcohols and the like, and acetylenic group-containing alcohols are preferably used. Two or more thereof may be contained. By containing these reaction inhibitors, the curing rate of the silicone rubber layer can be adjusted. The content of the reaction inhibitor in the silicone rubber layer composition is preferably 0.01% by mass or more and 20% by mass or less, and more preferably 0.1% by mass or more and 15% by mass or less. When the content of the reaction inhibitor is 0.01% by mass or more in the silicone rubber layer composition, it is possible to ensure the stability of the silicone rubber layer composition and its solution, and when the content is 20% by mass or less, the curability of the silicone rubber layer is not significantly degraded.

The curing catalyst can be selected from those known in the art. Platinum-based compounds are preferable, and specific examples thereof include elemental platinum, platinum chloride, chloroplatinic acid, olefin coordination platinum, platinum alcohol-modified complexes, platinum methyl vinyl polysiloxane complexes and the like. Two or more thereof may be contained. The content of the curing catalyst is preferably 0.001% by mass or more and 20% by mass or less in the silicone rubber layer composition, and more preferably 0.01% by mass or more and 15% by mass or less. The silicone rubber layer can be sufficiently cured when the content of the curing catalyst is 0.001% by mass or more, and the stability of the silicone rubber layer composition and its solution can be ensured when the curing catalyst content is 20% by mass or less.

The ink repellent layer may also contain a compound represented by the general formula (IV) for the purpose of improving the adhesion to other adjacent layers.

R—Si—(X)₃ (IV)

In the general formula (IV), R represents an alkyl group, an aryl group or a vinyl group, and X represents an acetoxy group or a dialkyloxyimino group.

When the ink repellent layer containing the compound represented by the general formula (IV) is in contact with the heat sensitive layer, the adhesion between the ink repellent layer and the heat sensitive layer becomes stronger because the compound represented by the general formula (IV) and the hydroxyl group and imino group on the surface of the heat sensitive layer are bonded through a condensation reaction. This suppresses peeling from the interface between the ink repellent layer and the heat sensitive layer and destruction near the surface of the heat sensitive layer during printing, and can significantly improve the printing durability.

The content of the compound represented by the general formula (IV) is preferably 18 by mass or more and 20% by mass or less in the silicone rubber layer composition, and more preferably 4% by mass or more and 10% by mass or less. When the content of the compound is 18 by mass or more, the adhesion to the adjacent other layer can be improved, and when the content of the compound is 20% by mass or less, deterioration of the image reproducibility due to excessive adhesion of the ink repellent layer can be suppressed.

In the printing plate precursor according to the first aspect of the present invention, when at least a part thereof is irradiated with 100 mJ/cm2 of infrared rays, the range of reflection densities between the exposed area and the non-exposed area measured from the ink repellent layer side using a spectrophotometer filtered with any one of cyan, yellow, magenta and black filters is preferably 0.30 or more. When the range of reflection densities between the exposed area and the non-exposed area is 0.30 or more, it is possible to more increase the contrast between the image area and the non-image area by irradiation with infrared rays, and when the image pattern is discriminated by a machine, followed by rearrangement and/or classification, the reading accuracy can be improved. The range of reflection densities is preferably 0.35 or more, more preferably 0.45 or more, and still more preferably 0.50 or more.

The range of reflection densities between the image area and the non-image area can be measured using spectrophotometer (e.g., “exact” Advance manufactured by X-Rite, Inc.). For samples collected from the waterless planographic printing plate precursor, the average value obtained by measuring the reflection densities of the non-image area and the image area ten times, respectively, from the ink repellent layer side using a spectrophotometer filtered with a filter selected from cyan, magenta, yellow and black filters is defined as reflection densities of the image area and the non-image area when applying each filter. The absolute value of (reflection densities of the non-image area-reflection densities of the image area) is defined as a range of reflection densities, and the range of reflection densities when applying cyan, magenta, yellow and black filters are defined as ΔD_{C}, ΔD_{M}, ΔD_{Y} and ΔD_{K}, respectively. The largest value of ΔD_{C}, ΔD_{Y}, ΔD_{M} and ΔD_{K} is defined as the range of reflection densities, and the contrast is evaluated.

In the printing plate precursor according to the second aspect of the present invention, when at least a part of the waterless planographic printing plate precursor is irradiated with 100 mJ/cm² of infrared rays, a range of reflection densities ΔD_{C} between an exposed area and a non-exposed area measured from the ink repellent layer side using a cyan-filtered spectrophotometer is 0.30 or more. When the range of reflection densities ΔD_{C} between the exposed area and the non-exposed area is 0.30 or more, it is possible to more increase the contrast between the image area and the non-image area by irradiation with infrared rays, and when the image pattern is discriminated by a machine, followed by rearrangement and/or classification, the reading accuracy can be improved. The range of reflection densities ΔD_{C} is preferably 0.35 or more, more preferably 0.45 or more, and still more preferably 0.50 or more.

Examples of the method for setting a range of reflection densities between the exposed area and the non-exposed area at 0.30 or more include a method in which a substrate having a white color layer or a white color surface is combined with a heat sensitive layer containing (a) an infrared-absorbing dye, (b) a dye, and (c) a proton-donating compound, and the like. To increase ΔD_{C}, it is possible to exemplify a method using, as the dye (b), a dye having a maximum absorption wavelength in the range of 500 to 650 nm when accepting protons.

### Method of Producing Waterless Planographic Printing Plate

The method for producing a waterless planographic printing plate of the present invention will be described. The method for producing a waterless planographic printing plate includes (1) the step of exposing the planographic printing plate precursor of the present invention to form an image area and a non-image area (hereinafter sometimes referred to as “step (1)”). After the step (1), the method preferably includes (2) the step of removing the ink repellent layer of the image area of the exposed waterless planographic printing plate precursor (hereinafter sometimes referred to as “step (2)”).

First, the step (1) will be described. Examples of the light sources used for exposure include those in which the emission wavelength range is in the range of 300 nm to 1,500 nm. Of these, a semiconductor laser or YAG laser each having a light emitting wavelength range in the vicinity of the near infrared range is preferably used since it is widely used as the absorption wavelength of the heat sensitive layer. Specifically, laser light having a wavelength of 780 nm, 830 nm or 1064 nm is preferably used from the viewpoint of the conversion efficiency to heat.

The exposure energy is preferably 70 to 200 mJ/cm², and more preferably 90 to 110 mJ/cm², in terms of the image reproducibility, productivity, and suppression of peeling of the ink repellent layer.

It is possible to evaluate the contrast between the image area and the non-image area of the waterless planographic printing plate after step (1) by the reflection densities as mentioned above.

In the present invention, the range of reflection densities ΔD_{C} between an exposed area and a non-exposed area measured from the ink repellent layer side using a cyan-filtered spectrophotometer of an image area and a non-image area of the waterless planographic printing plate, after (1) the step of imagewise exposing to form an image area and a non-image area is preferably 0.30 or more, and the reading accuracy can be improved in the method for sorting a waterless planographic printing plate mentioned below. The range of reflection densities ΔD_{C} is more preferably set at 0.35 or more, still more preferably 0.45 or more, and yet more preferably 0.50 or more.

Examples of the method of setting the range of reflection densities ΔD_{C} at 0.30 or more include a method using the printing plate precursor of the present invention mentioned above.

Subsequently, the step (2) will be described. The ink repellent layer of the exposed area (image area) is removed by giving physical stimulation to the printing plate precursor after exposure. Examples of the method of giving physical stimulation include (i) a method of rubbing a plate surface using non-woven fabric, absorbent cotton, cloth, sponge, rubber or the like in the absence of a liquid, (ii) a method of wiping a plate surface using water-impregnated non-woven fabric, absorbent cotton, cloth, sponge or the like, (iii) a method of rubbing a plate surface using a rotating brush while showering water, (iv) a method of spraying high pressure water, warm water, and water vapor onto a plate surface and the like.

In the step (2), the waterless planographic printing plate precursor of the present invention is capable of performing chemical-free development without the use of a chemical solution containing an organic solvent, such as conventional pre-treatment liquid, developer or post-treatment liquid. Since chemical free development does not dissolve the heat sensitive layer with the chemical solution for development, peeling of the ink repellent layer can be significantly suppressed.

The development step can be partially or entirely performed automatically by an automatic developing machine. Examples of automatic developing machines include TWP-680 series (manufactured by HEIGHTS), TWP-1250 series (manufactured by HEIGHTS), TWL-650 series (manufactured by Toray Industries Inc.), TWL-860 series (manufactured by Toray Industries Inc.), TWL-1160 series (manufactured by Toray Industries Inc.) and the like, and automatic developing machines in which the cradle is dented in a curved shape to suppress the occurrence of scratches on the backside of the plate as mentioned in JP 5-6000 A. These may be used in combination.

In case developed flat-plate printing plates are stacked and stored, it is preferable to place a laminating paper between the plates for the purpose of protecting the plate surface.

### Method for Sorting Waterless Planographic Printing Plate

The waterless planographic printing plate of the present invention can form an image pattern that can read information by the machine, such as management number for management, one-dimensional code (such as bar code), two-dimensional code (such as “QR code” (registered trademark), micro “QR code” (registered trademark), DataMatrix, MaxCode, PDF417, MicroPDF 417, etc.), other than an image for printing, on the plate surface. The image pattern for management formed on such waterless planographic printing plate can be discriminated by a machine, and the waterless planographic printing plate can be sorted by automatically rearranging and/or classifying the waterless planographic printing plate. Examples of such system capable of sorting include Plate Sorting system of NELA, Inc. The waterless planographic printing plate of the present invention has high contrast between the exposed area and the non-exposed area, and can improve the reading accuracy by the machine when used in such a system.

### Method for Producing Printed Matter

The method for producing a printed matter from the waterless planographic printing plate of the present invention will be described. The method for producing a printed material according to the present invention includes the steps of adhering an ink to a surface of the waterless planographic printing plate obtained by the method for producing the planographic printing plate of the present invention, and transferring the ink directly or via a blanket to a printable medium. It is preferable to use, as the waterless planographic printing plate, a waterless planographic printing plate sorted by the sorting method mentioned above.

The waterless planographic printing plate is a planographic printing plate capable of printing without using a dampening solution. The layer derived from the heat sensitive layer serves as an ink-receiving layer, which serves as an image area. The ink repellent layer is a non-image area. The ink-receiving layer and the ink-rebound layer are almost in the same plane, with only micron-order steps between them. The ink is transferred to a printable medium for printing after the ink is applied only to the image area by utilizing a difference in ink adhesion. Examples of the printable medium include thin paper, cardboard, film, label and the like. Transfer of the ink may also be performed directly from the waterless planographic printing plate to the substrate or through the blanket.

It is possible to use, as the ink for use in the method for producing a printed material according to the present invention, oil-based inks used in newspaper and commercial printing, inks capable of being cured by active energy rays and the like. Ink cured by ultraviolet rays (hereinafter sometimes referred to as “UV ink”) generally contains a reactive monomer or reactive oligomer, a photopolymerization initiator, and optionally photosensitive components polymerizable by ultraviolet rays, such as a sensitizer and a photosensitive resin. Ink cured by irradiation with electron beam (hereinafter sometimes referred to as “EB ink”) generally contains photosensitive components polymerizable by electron beams, such as a reactive monomer or a reactive oligomer and a photosensitive resin.

An offset printing machine is preferable as the printing machine used to produce printed materials from the waterless planographic printing plate of the present invention. Both a sheet-fed printing machine and a rotary printing machine can be used.

### EXAMPLES

Hereinafter, the present invention will be described in more detail by way of Examples. The evaluation in the respective Examples and Comparative Examples was performed by the following methods.

### (I) Production of Waterless Planographic Printing Plate

(1) Step of Exposing in Accordance with Desired Image to Form Image Area and Non-Image Area

Samples each having a size of 670 mm×560 mm were taken from the waterless planographic printing plate precursors obtained by the respective Examples and Comparative Examples, and then mounted on an exposure machine (“PlateRite” 8900E, manufactured by SCREEN Graphic Solutions Co., Ltd.). Each sample was exposed at irradiation energy of 100 mJ/cm² to form an image area and a non-image area. In the image area, 10 sets of 100 dots having a size of 20 μm×20 μm and dots having a size of 10 μm×20 μm were formed at a resolution of 2,400 dpi and an interval of 1,75 lpi, as an image for evaluation of an image reproduction ratio.

### (2) Step of Removing Ink Repellent Layer of Image Area of Exposed Waterless Planographic Printing Plate Precursor

The waterless planographic printing plate precursor exposed by the above method (1) was passed through an automatic developing machine TWL-1160 F (manufactured by Toray Industries Inc.) at a transport speed of 60 cm/min to remove an ink repellent layer of the image area, thus producing a waterless planographic printing plate. For the Examples, Comparative Examples 1 and 3, a pre-treatment liquid containing an organic solvent, a developer, a post-treatment liquid and the like were not used and a developing tank of an automatic developing machine was refilled with only water, and then “water development” of rubbing a plate surface by a rotating brush while applying water was performed. For Comparative Example 2, a pre-treatment tank of the automatic developing machine was refilled with “NP-1” (pre-treatment liquid for waterless planographic negative type, manufactured by Toray Industries Inc.) and water was supplied to the developing tank, respectively, and then the resulting waterless planographic printing plate precursor was subjected to “chemical development”.

### (II) Evaluation of Image Reproducibility

The respective 100 dots having a size of 20 μm×20 μm size and having a size of 10 μm×20 μm size of the waterless planographic printing plate obtained by the above (I) were observed by a loupe at a magnification of 25 times. In each dot, if the ink repellent layer of the image area was removed after development, it was determined that the image was reproduced. If the ink repellent layer of the image area was not removed after development, it was determined that the image was not reproduced. For those with the lowest image reproducibility among 10 sets, the image reproducibility was evaluated by counting the number of microdots reproduced in 100 dots as the image reproducibility (%).

If the image reproduction ratio was 80% or higher in dots having a size of 20 μm×20 μm, it was determined to be acceptable for practical use, and if the image reproduction ratio was 100%, it was determined to be satisfactory. Furthermore, if the image reproduction ratio was 100% in dots having a size of 20 μm×20 μm and the image reproduction ratio was 30% or more in dots having a size of 10 μm×20 μm, it was determined to be very satisfactory.

### (III) Evaluation of Peeling Resistance of Ink Repellent Layer

Samples each having a size of 670 mm×560 mm were taken from the waterless planographic printing plate precursors obtained by the respective Examples and Comparative Examples, and then mounted on an exposure machine (“PlateRite” 8900E, manufactured by SCREEN Graphic Solutions Co., Ltd.). Each sample was exposed at irradiation energy of 200 mJ/cm², which is the upper limit of practically desirable irradiation energy, to form an image area and a non-image area. These exposure conditions are severe enough to accelerate thermal decomposition near the boundary between the ink repellent layer and the heat sensitive layer and weaken the adhesive strength of the ink repellent layer and the heat sensitive layer, leading to a state where the ink repellent layer is easily peeled off. A solid image of 100 mm×100 mm was formed in the image area. Thereafter, the exposed waterless planographic printing plate precursor was passed through an automatic developing machine TWL-1160 F (manufactured by Toray Industries Inc.) while changing a transport speed in the range from 40 cm/min to 80 cm/min every 10 cm/min to remove the ink repellent layer of the image area. For the respective Examples and Comparative Examples 1 and 3, a developing tank of the automatic developing machine was refilled with only water, and for Comparative Example 2, the developing tank was refilled with water, and the pre-treatment tank was refilled with “NP-1”. Shearing stress was applied to the ink repellent layer by rubbing the plate surface using a brush rotating while spraying water, leading to a state where the ink repellent layer is easily peeled off. The boundary between the solid image area and the non-image area was observed, and peeling of the ink repellent layer was observed and, and the peeling resistance of the ink repellent layer was evaluated based on the highest transport speed at which peeling of the ink repellent layer was observed in the non-image area.

It is preferable that no peeling of the ink repellent layer is observed even at low transport speed that increases the time required for the application of shearing stress. The score is 5 points if peeling of the ink repellent layer is not observed even at slow transport speed of 40 cm/min; 4 points if peeling is observed at 40 cm/min but not observed at 50 cm/min; 3 points if peeling is observed at 50 cm/min but not observed at 60 cm/min; 2 points if peeling is observed at 60 cm/min but not observed at 70 cm/min; 1 point if peeling is observed at 70 cm/min but not observed at 80 cm/min; and 0 point if peeling is observed even at 80 cm/min.

In terms of latitude in the manufacture of the waterless planographic printing plate, the score of 1 or higher is practically acceptable, the score of 3 or higher is preferable, and the score of 5 is more preferable.

### (IV) Evaluation of Contrast between Image Area and Non-Image Area

For the waterless planographic printing plate precursor obtained by “(1) Step of exposing in accordance with a desired image to form image area and non-image area”, reflection densities of the non-image area and the image area were measured using a spectrophotometer “exact” Advance manufactured by X-Rite, Inc., and then a range of reflection densities between the non-image area and the image area was calculated. The measurement was taken with cyan, yellow, magenta or black filters applied, respectively, and the average of 10 measurements each in the image area and non-image area was defined as the reflection densities of the image area and non-image area. The highest value among the absolute values ΔD_{C}, ΔD_{Y}, ΔD_{M} and ΔD_{K} of each (reflection densities of non-image area—reflection densities of image area) was used as the range of reflection densities, and then the contrast was evaluated. The plate was judged to be practically acceptable if the range of reflection densities is 0.30 or more, generally satisfactory if the range of reflection densities is 0.35 or more, satisfactory if the range of reflection densities is 0.45 or more, and very satisfactory if the range of reflection densities is 0.50 or more.

### Example 1

A waterless planographic printing plate precursor was fabricated by the following method.

### Substrate having White Color Surface

The surface of a 0.24 mm thick degreased aluminum substrate (manufactured by Mitsubishi Aluminum Co., Ltd.) was grained using three nylon brushes implanted with 0.3 mm single fiber diameter bundles and a pumice (having 25 μm median diameter)-water suspension (having a specific gravity of 1.1 g/cm³) and then washed well with water. This substrate was etched by immersing in an aqueous 25% by mass sodium hydroxide solution at 45° C. for 9 seconds, washed with water, immersed in 20% by mass nitric acid at 60° C. for 20 seconds and then washed with water.

Subsequently, the grained aluminum substrate was continuously subjected to an electrochemical roughening treatment in an electrolytic solution using an AC voltage of 60 Hz. At this time, the electrolytic solution was an aqueous 1% by mass nitric acid solution (containing 0.5% by mass of aluminum ions) at a liquid temperature of 50° C.

Using an AC power supply waveform, which is a trapezoidal rectangular wave AC in which the time TP until the current value reaches the peak from zero is 0.8 msec and the duty ratio is 1:1, and using a carbon electrode as a counter electrode, an electrochemical roughening treatment was performed. Ferrite was used as an auxiliary anode. The current density was 30 A/dm² at a peak value of the current and 5% of a current flowing from a power source was diverted to the auxiliary anode. The amount of electricity in nitric acid electrolysis was 175 C/dm² electricity when the aluminum substrate was the anode. Then, the substrate was washed with water by spraying.

Subsequently, an electrochemical roughening treatment was performed by in the same manner as in the nitric acid electrolysis under the conditions that the amount of electricity became 50 C/dm² when the aluminum substrate was used as the anode using an aqueous 0.5% by mass hydrochloric acid solution (containing 0.5% by mass of aluminum ions) and an electrolytic solution having a liquid temperature of 50° C., and then the substrate was washed with water by spraying.

This substrate was provided with a DC anodic oxide coating (2.5 g/m²) at a current density of 15 A/dm² using a 15% sulfuric acid (containing 0.5% by mass of aluminum ions) as an electrolytic solution, and after washing with water and drying, the substrate was further immersed in an aqueous 2.5% by mass sodium silicate solution at 30° C. for 10 seconds to obtain a substrate having a white color surface. The center line average roughness (Ra) of the resulting substrate having a white color surface was 0.51 μm, and the reflectance was 50% or more in the full wavelength range of 450 to 700 nm.

Subsequently, the following heat sensitive layer composition solution-1 was applied on the substrate having a white color surface and then heated and dried at 140° C. for 90 seconds to provide a 1.5 μm thick heat sensitive layer. The heat sensitive layer composition solution-1 was obtained by stirring and mixing the following components at room temperature.

### Heat Sensitive Layer Composition Solution-1

(i) Methylol-based methylated melamine resin: “CYMEL” (registered trademark) 370 (manufactured by Allnex, viscosity: 5,100 to 10,200 mPa·s) 83.0 parts by mass
(ii) Infrared-absorbing dye (Cyanine dye): NK5559 (manufactured by HAYASHIBARA CO., LTD., maximum absorption wavelength: 774 nm): 11.0 parts by mass
(iii) Dye that changes color by proton acceptance (azo compound having a maximum absorption wavelength of 420 nm when accepting protons): Metanil Yellow (manufactured by Tokyo Chemical Industry Co. Ltd.): 5.0 parts by mass
(iv) Proton-donating compound: p-toluenesulfonic acid: 1.0 parts by mass
(v) Tetrahydrofuran: 900 parts by mass

Subsequently, the following ink repellent layer (silicone rubber layer) composition solution prepared immediately before application was applied on the heat sensitive layer and heated at 140° C. for 80 seconds to provide an ink repellent layer with an average film thickness of 2.5 μm, thus obtaining a waterless planographic printing plate precursor. The ink repellent layer composition solution was obtained by stirring and mixing the following components at room temperature.

### Ink Repellent Layer Composition Solution

(i) α,ω-divinylpolydimethylsiloxane: DMS-V35 (weight-average molecular weight of 49, 500, manufactured by GELEST Inc.): 86.95 parts by mass
(ii) Methylhydrogensiloxane-dimethylsiloxane copolymer RD-1 ((II)/((II)+(III))=0.5; manufactured by Dow Corning Toray Co., Ltd.: 4.24 parts by mass
(iii) Vinyltris (methylethylketoxyimino) silane: 2.64 parts by mass
(iv) Platinum catalyst SRX212 (manufactured by Dow Corning Toray Co., Ltd.: 6.17 parts by mass
(v) “Isopar” (registered trademark) E (manufactured by Esso Chemicals): 900 parts by mass

The resulting waterless planographic printing plate precursor was evaluated by the above method, thus obtaining practically applicable results, that is, the image reproduction ratio was 90% for 20 μm×20 μm dots. The peeling resistance of the ink repellent layer was satisfactory, that is, the score was 3 points. The range of reflection densities ΔD_{Y} measured by applying a yellow filter was 0.30, that is, practically applicable results were obtained.

### Example 2

A waterless planographic printing plate precursor was obtained in the same manner as in Example 1, except for using, as the substrate having a white surface, “LUMIRROR” (registered trademark) #225-E6SR (white PET film, manufactured by Toray Industries Inc.), which has a reflectance of 70% or more in the full wavelength range of 450 to 700 nm.

The resulting waterless planographic printing plate precursor was evaluated by the above method, thus obtaining practically applicable results, that is, the image reproduction ratio was 90% for 20 μm×20 μm dots. The peeling resistance of the ink repellent layer was satisfactory, that is, the score was 3 points. The range of reflection densities ΔD _{Y} measured by applying a yellow filter was 0.31, that is, practically applicable results were obtained.

### Example 3

The following organic layer composition liquid-1 was applied on a 0.24 mm thick degreased aluminum substrate (manufactured by Mitsubishi Aluminum Co., Ltd.) and then dried at 200° C. for 90 seconds to provide a 10.0 μm thick organic layer, thus obtaining a substrate having a white color layer. The resulting substrate having a white color layer had a reflectance of 75% or more in the full wavelength range of 450 to 700 nm. The organic layer composition liquid-1 was obtained by stirring and mixing the following components at room temperature. A waterless planographic printing plate precursor was obtained in the same manner as in Example 1, except that the substrate having a white color surface was changed to the substrate having a white color layer.

### Organic Layer Composition Liquid-1

(i) Polymer containing active hydrogen: Epoxy resin: “jER” (registered trademark) 1010 (manufactured by Mitsubishi Chemical Corporation): 29.2 parts by mass
(ii) Polymer containing active hydrogen: Polyurethane: “SANPRENE” LQ-T1331D (manufactured by Sanyo Chemical Industries Ltd., solid content concentration: 20% by mass): 51.7 parts by mass
(iii) Aluminum chelate: aluminum chelate ALCH-TR (manufactured by Kawaken Fine Techno Co. Ltd.): 4.5 parts by mass
(iv) Leveling agent: “Disparlon (registered trademark) LC 951 (manufactured by Kusumoto Chemicals Ltd., solid content: 10% by mass): 0.1 part by mass
(v) Titanium oxide: “Tipaque” (registered trademark) CR-50 (N,N-dimethylformamide dispersion (titanium oxide of 50% by mass) manufactured by Ishihara Sangyo Kaisya, Ltd.): 14.5 parts by mass
(vi) N,N-dimethylformamide: 450 parts by mass
(vii) Methyl ethyl ketone: 150 parts by mass

The resulting waterless planographic printing plate precursor was evaluated by the above method, thus obtaining practically applicable results, that is, the image reproduction ratio was 90% for 20 μm×20 μm dots. The peeling resistance of the ink repellent layer was satisfactory, that is, the score was 3 points. The range of reflection densities ΔD_{Y} measured by applying a yellow filter was 0.33, that is, practically applicable results were obtained.

### Example 4

A planographic printing plate precursor was obtained in the same manner as in Example 3, except that the heat sensitive layer composition solution-1 was changed to the following heat sensitive layer composition solution-2.

### Heat Sensitive Layer Composition Solution-2

(i) Methylol-based methylated melamine resin: “CYMEL” (registered trademark) 370 (manufactured by Allnex, viscosity: 5,100 to 10,200 mPa·s): 82.0 parts by mass
(ii) Infrared-absorbing dye (Cyanine dye): NK 5559 (manufactured by HAYASHIBARA CO., LTD., maximum absorption wavelength: 774 nm): 12.0 parts by mass
(iii) Dye that changes color by proton acceptance (azo compound having a maximum absorption wavelength of 420 nm when accepting protons): Metanil Yellow (manufactured by Tokyo Chemical Industry Co., Ltd.): 5.0 parts by mass
(iv) Proton-donating compound: p-toluenesulfonic acid: 1.0 parts by mass
(v) Tetrahydrofuran: 900 parts by mass

The resulting waterless planographic printing plate precursor was evaluated by the above method, thus obtaining satisfactory image reproducibility, that is, the image reproduction ratio was 100% for 20 μm×20 μm dots, and 10% for 10 μm×20 μm dots. The peeling resistance of the ink repellent layer was satisfactory, that is, the score was 3 points. The range of reflection densities ΔD_{Y} measured by applying a yellow filter was 0.33, that is, practically applicable results were obtained.

### Example 5

A planographic printing plate precursor was obtained as in Example 3, except that the heat sensitive layer composition solution-1 was changed to the following heat sensitive layer composition solution-3.

### Heat Sensitive Layer Composition Solution-3

(i) Methylol-based methylated melamine resin: “CYMEL” (registered trademark) 370 (manufactured by Allnex, viscosity: 5,100 to 10,200 mPa·s): 80.0 parts by mass
(ii) Infrared-absorbing dye (Cyanine dye): NK 5559 (manufactured by HAYASHIBARA CO., LTD., maximum absorption wavelength: 774 nm): 14.0 parts by mass
(iii) Dye that changes color by proton acceptance (azo compound having a maximum absorption wavelength of 420 nm when accepting protons): Metanil Yellow (manufactured by Tokyo Chemical Industry Co., Ltd.): 5.0 parts by mass
(iv) Proton-donating compound: p-toluenesulfonic acid: 1.0 parts by mass
(v) Tetrahydrofuran: 900 parts by mass

The resulting waterless planographic printing plate precursor was evaluated by the above method, thus obtaining very satisfactory image reproducibility, that is, the image reproduction ratio was 100% for 20 μm×20 μm dots, and 30% for 10 μm×20 μm dots. The peeling resistance of the ink repellent layer was satisfactory, that is, the score was 3 points. The range of reflection densities ΔD_{Y} measured by applying a yellow filter was 0.35, that is, generally satisfactory results were obtained.

### Example 6

A planographic printing plate precursor was obtained as in Example 3, except that the heat sensitive layer composition solution-1 was changed to the following heat sensitive layer composition solution-4.

### Heat Sensitive Layer Composition Solution-4

(i) Methylol-based methylated melamine resin: “CYMEL” (registered trademark) 370 (manufactured by Allnex, viscosity: 5,100 to 10,200 mPa·s): 76.0 parts by mass
(ii) Infrared-absorbing dye (Cyanine dye): NK5559 (manufactured by HAYASHIBARA CO., LTD., maximum absorption wavelength: 774 nm): 18.0 parts by mass
(iii) Dye that changes color by proton acceptance (azo compound having a maximum absorption wavelength of 420 nm when accepting protons): Metanil Yellow (manufactured by Tokyo Chemical Industry Co., Ltd.): 5.0 parts by mass
(iv) Proton-donating compound: p-toluenesulfonic acid: 1.0 parts by mass
(v) Tetrahydrofuran: 900 parts by mass

The resulting waterless planographic printing plate precursor was evaluated by the above method, thus obtaining very satisfactory image reproducibility, that is, the image reproduction ratio was 100% for 20 μm×20 μm dots, and 55% for 10 μm×20 μm dots. The peeling resistance of the ink repellent layer was satisfactory, that is, the score was 3 points. The range of reflection densities ΔD_{Y} measured by applying a yellow filter was 0.40, that is, generally satisfactory results were obtained.

### Example 7

A planographic printing plate precursor was obtained in the same manner as in Example 3, except that the heat sensitive layer composition solution-1 was changed to the following heat sensitive layer composition solution-5.

### Heat Sensitive Layer Composition Solution-5>

(i) Methylol-based methylated melamine resin: “CYMEL” (registered trademark) 370 (manufactured by Allnex, viscosity: 5,100 to 10,200 mPa·s): 74.0 parts by mass
(ii) Infrared-absorbing dye (Cyanine dye): NK5559 (manufactured by HAYASHIBARA CO., LTD., maximum absorption wavelength: 774 nm): 20.0 parts by mass
(iii) Dye that changes color by proton acceptance (azo compound having a maximum absorption wavelength of 420 nm when accepting protons): Metanil Yellow (manufactured by Tokyo Chemical Industry Co., Ltd.): 5.0 parts by mass
(iv) Proton-donating compound: p-toluenesulfonic acid: 1.0 parts by mass
(v) Tetrahydrofuran: 900 parts by mass

The resulting waterless planographic printing plate precursor was evaluated by the above method, thus obtaining very satisfactory image reproducibility, that is, the image reproduction ratio was 100% for 20 μm×20 μm dots, and 70% for 10 μm×20 μm dots. The peeling resistance of the ink repellent layer was satisfactory, that is, the score was 2 points. The range of reflection densities ΔD_{Y} measured by applying a yellow filter was 0.42, that is, generally satisfactory results were obtained.

### Example 8

A planographic printing plate precursor was obtained in the same manner as in Example 3, except that the heat sensitive layer composition solution-1 was changed to the following heat sensitive layer composition solution-6.

### Heat Sensitive Layer Composition Solution-6

(i) Methylol-based methylated melamine resin: “CYMEL” (registered trademark) 370 (manufactured by Allnex, viscosity: 5,100 to 10,200 mPa·s) 69.0 parts by mass
(ii) Infrared-absorbing dye (Cyanine dye): NK5559 (manufactured by HAYASHIBARA CO., LTD., maximum absorption wavelength: 774 nm): 25.0 parts by mass
(iii) Dye that changes color by proton acceptance (azo compound having a maximum absorption wavelength of 420 nm when accepting protons): Metanil Yellow (manufactured by Tokyo Chemical Industry Co., Ltd.): 5.0 parts by mass
(iv) Proton-donating compound: p-toluenesulfonic acid: 1.0 parts by mass
(v) Tetrahydrofuran: 900 parts by mass

The resulting waterless planographic printing plate precursor was evaluated by the above method, thus obtaining very satisfactory image reproducibility, that is, the image reproduction ratio was 100% for 20 μm×20 μm dots, and 80% for 10 μm×20 μm dots. The peeling resistance of the ink repellent layer was 1 point. The range of reflection densities ΔD_{Y} measured by applying a yellow filter was 0.42, that is, generally satisfactory results were obtained.

### Example 9

A planographic printing plate precursor was obtained in the same manner as in Example 3, except that the heat sensitive layer composition solution-1 was changed to the following heat sensitive layer composition solution-7.

### Heat Sensitive Layer Composition Solution-7

(i) Methylol-based methylated melamine resin: “CYMEL” (registered trademark) 370 (manufactured by Allnex, viscosity: 5,100 to 10,200 mPa·s): 80.0 parts by mass
(ii) Infrared-absorbing dye (Cyanine dye): NK 5559 (manufactured by HAYASHIBARA CO., LTD., maximum absorption wavelength: 774 nm): 14.0 parts by mass
(iii) Dye that changes color by proton acceptance (leuco dye having a maximum absorption wavelength of 480 nm when accepting protons): RED 520 (2-methyl-6-(N-p-tolyl-N-ethylamino)-fluoran), manufactured by Fukui Yamada Chemical Co., Ltd.: 5.0 parts by mass
(iv) Proton-donating compound: p-toluenesulfonic acid: 1.0 parts by mass
(v) Tetrahydrofuran: 900 parts by mass

The resulting waterless planographic printing plate precursor was evaluated by the above method, thus obtaining very satisfactory image reproducibility, that is, the image reproduction ratio was 100% for 20 μm×20 μm dots, and 30% for 10 μm×20 μm dots. The peeling resistance of the ink repellent layer was satisfactory, that is, the score was 3 points. The range of reflection densities ΔD_{Y} measured by applying a yellow filter was 0.45, that is, satisfactory results were obtained.

### Example 10

A planographic printing plate precursor was obtained in the same manner as in Example 3, except that the heat sensitive layer composition solution-1 was changed to the following heat sensitive layer composition solution-8.

### Heat Sensitive Layer Composition Solution-8

(i) Methylol-based methylated melamine resin: “CYMEL” (registered trademark) 370 (manufactured by Allnex, viscosity: 5,100 to 10,200 mPa·s): 80.0 parts by mass
(ii) Infrared-absorbing dye (Cyanine dye): NK 5559 (manufactured by HAYASHIBARA CO., LTD., maximum absorption wavelength: 774 nm): 14.0 parts by mass
(iii) Dye that changes color by proton acceptance (Leuco dye having a maximum absorption wavelength of 570 nm when accepting protons): Blue 203 (3-[4-(diethylamino)-2-hexyloxyphenyl]-3-(1-ethyl-2-methylindol-3-yl)-4-azaphthalide, manufactured by Fukui Yamada Chemical Co., Ltd.: 5.0 parts by mass
(iv) Proton-donating compound: p-toluenesulfonic acid: 1.0 parts by mass
(v) Tetrahydrofuran: 900 parts by mass

The resulting waterless planographic printing plate precursor was evaluated by the above method, thus obtaining very satisfactory image reproducibility, that is, the image reproduction ratio was 100% for 20 μm×20 μm dots, and 30% for 10 μm×20 μm dots. The peeling resistance of the ink repellent layer was satisfactory, that is, the score was 3 points. The range of reflection densities ΔD_{C} measured by applying a cyan filter was 0.48, that is, satisfactory results were obtained.

### Example 11

A planographic printing plate precursor was obtained in the same manner as in Example 3, except that the heat sensitive layer composition solution-1 was changed to the following heat sensitive layer composition solution-9.

### Heat Sensitive Layer Composition Solution-9

(i) Infrared-absorbing dye (Cyanine dye): NK 5559 (manufactured by HAYASHIBARA CO., LTD., maximum absorption wavelength: 774 nm): 14.0 parts by mass
(ii) Dye that changes color by proton acceptance (Leuco dye having a maximum absorption wavelength of 570 nm when accepting protons): Blue 203 (3-[4-(diethylamino)-2-hexyloxyphenyl]-3-(1-ethyl-2-methylindol-3-yl)-4-azaphthalide, manufactured by Fukui Yamada Chemical Co., Ltd.: 5.0 parts by mass
(iii) Proton-donating compound (polymer including active hydrogen-containing structural unit): poly (methacrylic acid) (manufactured by FUJIFILM Wako Pure Chemical Corporation): 81.0 parts by mass
(iv) Tetrahydrofuran: 900 parts by mass

The resulting waterless planographic printing plate precursor was evaluated by the above method, thus obtaining very satisfactory image reproducibility, that is, the image reproduction ratio was 100% for 20 μm×20 μm dots, and 30% for 10 μm×20 μm dots. The peeling resistance of the ink repellent layer was satisfactory, that is, the score was 4 points. The range of reflection densities ΔD_{C} measured by applying a cyan filter was 0.48, that is, satisfactory results were obtained.

### Example 12

A planographic printing plate precursor was obtained in the same manner as in Example 3, except that the heat sensitive layer composition solution-1 was changed to the following heat sensitive layer composition solution-10.

### Heat Sensitive Layer Composition Solution-10

(i) Infrared-absorbing dye (Cyanine dye): NK 5559 (manufactured by HAYASHIBARA CO., LTD., maximum absorption wavelength: 774 nm): 14.0 parts by mass
(ii) Dye that changes color by proton acceptance (Leuco dye having a maximum absorption wavelength of 570 nm when accepting protons): Blue 203 (3-[4-(diethylamino)-2-hexyloxyphenyl]-3-(1-ethyl-2-methylindol-3-yl)-4-azaphthalide, manufactured by Fukui Yamada Chemical Co., Ltd.: 5.0 parts by mass
(iii) Proton-donating compound (polymer having active hydrogen-containing structural unit): Phenol formaldehyde novolac resin “Sumilite resin” (registered trademark) PR53195 (manufactured by Sumitomo Bakelite Co., Ltd.): 64.8 parts by mass
(iv) Organic complex compound: Titanium-n-butoxide bis (acetylacetonate): “Nācem” (registered trademark) titanium (manufactured by NIHON KAGAKU SANGYO CO., LTD., concentration: 73% by mass, containing n-butanol: 27% by mass as solvent): 16.2 parts by mass
(v) Tetrahydrofuran: 900 parts by mass

The resulting waterless planographic printing plate precursor was evaluated by the above method, thus obtaining very satisfactory image reproducibility, that is, the image reproduction ratio was 100% for 20 μm×20 μm dots, and 30% for 10 μm×20 μm dots. The peeling resistance of the ink repellent layer was very satisfactory, that is, the score was 5 points. The range of reflection densities ΔD_{C} measured by applying a cyan filter was 0.48, that is, satisfactory results were obtained.

### Example 13

A planographic printing plate precursor was obtained in the same manner as in Example 3, except that the heat sensitive layer composition solution-1 was changed to the following heat sensitive layer composition solution-11.

### Heat Sensitive Layer Composition Solution-11

(i) Infrared-absorbing dye (Cyanine dye): NK5559 (manufactured by HAYASHIBARA CO., LTD., maximum absorption wavelength: 774 nm): 11.0 parts by mass
(ii) Dye that changes color by proton acceptance (Leuco dye having a maximum absorption wavelength of 580 nm when accepting protons): FB-1 (3′,6′-bis(diphenylamino)spiro[phthalide-3,9′-xanthene], manufactured by Fukui Yamada Chemical Co., Ltd.: 5.0 parts by mass
(iii) Proton-donating compound (polymer including active hydrogen-containing structural unit): Phenol formaldehyde novolac resin “Sumilite resin” (registered trademark) PR53195 (manufactured by Sumitomo Bakelite Co., Ltd.): 67.2 parts by mass
(iv) Organic complex compound: Titanium-n-butoxide bis (acetylacetonate): “Nācem” (registered trademark) titanium (manufactured by NIHON KAGAKU SANGYO CO., LTD., concentration: 73% by mass, containing n-butanol: 27% by mass as solvent): 16.8 parts by mass
(v) Tetrahydrofuran: 900 parts by mass

The resulting waterless planographic printing plate precursor was evaluated by the above method, thus obtaining practically applicable results, that is, the image reproduction ratio was 90% for 20 μm×20 μm dots. The peeling resistance of the ink repellent layer was very satisfactory, that is, the score was 5 points. The range of reflection densities ΔD_{C} measured by applying a cyan filter was 0.43, that is, generally satisfactory results were obtained.

### Example 14

A planographic printing plate precursor was obtained in the same manner as in Example 3, except that the heat sensitive layer composition solution-1 was changed to the following heat sensitive layer composition solution-12.

### Heat Sensitive Layer Composition Solution-12

(i) Infrared-absorbing dye (Cyanine dye): NK 5559 (manufactured by HAYASHIBARA CO., LTD., maximum absorption wavelength: 774 nm): 12.0 parts by mass
(ii) Dye that changes color by proton acceptance (Leuco dye having a maximum absorption wavelength of 580 nm when accepting protons): FB-1 (3′,6′-bis(diphenylamino)spiro[phthalide-3,9′-xanthene], manufactured by Fukui Yamada Chemical Co., Ltd.: 5.0 parts by mass
(iii) Proton-donating compound (polymer including active hydrogen-containing structural unit): Phenol formaldehyde novolac resin “Sumilite resin” (registered trademark) PR53195 (manufactured by Sumitomo Bakelite Co., Ltd.): 66.4 parts by mass
(iv) Organic complex compound: Titanium-n-butoxide bis (acetylacetonate): “Nācem” (registered trademark) titanium (manufactured by NIHON KAGAKU SANGYO CO., LTD., concentration: 73% by mass, containing n-butanol: 27% by mass as solvent): 16.6 parts by mass
(v) Tetrahydrofuran: 900 parts by mass

The resulting waterless planographic printing plate precursor was evaluated by the above method, thus obtaining satisfactory image reproducibility, that is, the image reproduction ratio was 100% for 20 μm×20 μm dots, and 10% for 10 μm×20 μm dots. The peeling resistance of the ink repellent layer was very satisfactory, that is, the score was 5 points. The range of reflection densities ΔD_{C} measured by applying a cyan filter was 0.43, that is, generally satisfactory results were obtained.

### Example 15

A planographic printing plate precursor was obtained in the same manner as in Example 3, except that the heat sensitive layer composition solution-1 was changed to the following heat sensitive layer composition solution-13.

### Heat Sensitive Layer Composition Solution-13

(i) Infrared-absorbing dye (Cyanine dye): NK5559 (manufactured by HAYASHIBARA CO., LTD., maximum absorption wavelength: 774 nm): 18.0 parts by mass
(ii) Dye that changes color by proton acceptance (Leuco dye having a maximum absorption wavelength of 580 nm when accepting protons): FB-1 (3′,6′-bis(diphenylamino)spiro[phthalide-3,9′-xanthene], manufactured by Fukui Yamada Chemical Co., Ltd.: 5.0 parts by mass
(iii) Proton-donating compound (polymer including active hydrogen-containing structural unit): Phenol formaldehyde novolac resin “Sumilite resin” (registered trademark) PR53195 (manufactured by Sumitomo Bakelite Co., Ltd.): 61.6 parts by mass
(iv) Organic complex compound: Titanium-n-butoxide bis (acetylacetonate): “Nācem” (registered trademark) titanium (manufactured by NIHON KAGAKU SANGYO CO., LTD., concentration: 73% by mass, containing n-butanol: 27% by mass as solvent): 15.4 parts by mass
(v) Tetrahydrofuran: 900 parts by mass

The resulting waterless planographic printing plate precursor was evaluated by the above method, thus obtaining very satisfactory image reproducibility, that is, the image reproduction ratio was 100% for 20 μm×20 μm dots, and 55% for 10 μm×20 μm dots. The peeling resistance of the ink repellent layer was very satisfactory, that is, the score was 5 points. The range of reflection densities ΔD_{C} measured by applying a cyan filter was 0.50, that is, very satisfactory results were obtained.

### Example 16

A planographic printing plate precursor was obtained in the same manner as in Example 3, except that the heat sensitive layer composition solution-1 was changed to the following heat sensitive layer composition solution-14.

### Heat Sensitive Layer Composition Solution-14

(i) Infrared-absorbing dye (Cyanine dye): NK 5559 (manufactured by HAYASHIBARA CO., LTD., maximum absorption wavelength: 774 nm): 20.0 parts by mass
(ii) Dye that changes color by proton acceptance (Leuco dye having a maximum absorption wavelength of 580 nm when accepting protons): FB-1 (3′,6′-bis(diphenylamino)spiro[phthalide-3,9′-xanthene], manufactured by Fukui Yamada Chemical Co., Ltd.: 5.0 parts by mass
(iii) Proton-donating compound (polymer including active hydrogen-containing structural unit): Phenol formaldehyde novolac resin “Sumilite resin” (registered trademark) PR53195 (manufactured by Sumitomo Bakelite Co., Ltd.): 60.0 parts by mass
(iv) Organic complex compound: Titanium-n-butoxide bis (acetylacetonate): “Nācem” (registered trademark) titanium (manufactured by NIHON KAGAKU SANGYO CO., LTD., concentration: 73% by mass, containing n-butanol: 27% by mass as solvent): 15.0 parts by mass
(v) Tetrahydrofuran: 900 parts by mass

The resulting waterless planographic printing plate precursor was evaluated by the above method, thus obtaining very satisfactory image reproducibility, that is, the image reproduction ratio was 100% for 20 μm×20 μm dots, and 70% for 10 μm×20 μm dots. The peeling resistance of the ink repellent layer was satisfactory, that is, the score was 4 points. The range of reflection densities ΔD _{C} measured by applying a cyan filter was 0.52, that is, very satisfactory results were obtained.

### Example 17

A planographic printing plate precursor was obtained in the same manner as in Example 3, except that the heat sensitive layer composition solution-1 was changed to the following heat sensitive layer composition solution-15.

### Heat Sensitive Layer Composition Solution-15

(i) Infrared-absorbing dye (Cyanine dye): NK 5559 (manufactured by HAYASHIBARA CO., LTD., maximum absorption wavelength: 774 nm): 25.0 parts by mass
(ii) Dye that changes color by proton acceptance (Leuco dye having a maximum absorption wavelength of 580 nm when accepting protons): FB-1 (3′,6′-bis(diphenylamino)spiro[phthalide-3,9′-xanthene], manufactured by Fukui Yamada Chemical Co., Ltd.: 5.0 parts by mass
(iii) Proton-donating compound (polymer including active hydrogen-containing structural unit): Phenol formaldehyde novolac resin “Sumilite resin” (registered trademark) PR53195 (manufactured by Sumitomo Bakelite Co., Ltd.): 56.0 parts by mass
(iv) Organic complex compound: Titanium-n-butoxide bis (acetylacetonate): “Nācem” (registered trademark) titanium (manufactured by NIHON KAGAKU SANGYO CO., LTD., concentration: 73% by mass, containing n-butanol: 27% by mass as solvent): 14.0 parts by mass
(v) Tetrahydrofuran: 900 parts by mass

The resulting waterless planographic printing plate precursor was evaluated by the above method, thus obtaining very satisfactory image reproducibility, that is, the image reproduction ratio was 100% for 20 μm×20 μm dots, and 80% for 10 μm×20 μm dots. The peeling resistance of the ink repellent layer was satisfactory, that is, the score was 3 points. The range of reflection densities ΔD_{C} measured by applying a cyan filter was 0.52, that is, very satisfactory results were obtained.

### Example 18

A planographic printing plate precursor was obtained in the same manner as in Example 3, except that the heat sensitive layer composition solution-1 was changed to the following heat sensitive layer composition solution-16.

### Heat Sensitive Layer Composition Solution-16

(i) Infrared-absorbing dye (Cyanine dye): NK 5559 (manufactured by HAYASHIBARA CO., LTD., maximum absorption wavelength: 774 nm): 14.0 parts by mass
(ii) Dye that changes color by proton acceptance (Leuco dye having a maximum absorption wavelength of 580 nm when accepting protons): FB-1 (3′,6′-bis(diphenylamino)spiro[phthalide-3,9′-xanthene], manufactured by Fukui Yamada Chemical Co., Ltd.: 5.0 parts by mass
(iii) Proton-donating compound (polymer including active hydrogen-containing structural unit): Phenol formaldehyde novolac resin “Sumilite resin” (registered trademark) PR53195 (manufactured by Sumitomo Bakelite Co., Ltd.): 64.8 parts by mass
(iv) Organic complex compound: Titanium-n-butoxide bis (acetylacetonate): “Nācem” (registered trademark) titanium (manufactured by NIHON KAGAKU SANGYO CO., LTD., concentration: 73% by mass, containing n-butanol: 27% by mass as solvent): 16.2 parts by mass
(v) Tetrahydrofuran: 900 parts by mass

The resulting waterless planographic printing plate precursor was evaluated by the above method, thus obtaining very satisfactory image reproducibility, that is, the image reproduction ratio was 100% for 20 μm×20 μm dots, and 30% for 10 μm×20 μm dots. The peeling resistance of the ink repellent layer was very satisfactory, that is, the score was 5 points. The range of reflection densities ΔD_{C} measured by applying a cyan filter was 0.48, that is, satisfactory results were obtained.

### Example 19

A planographic printing plate precursor was obtained in the same manner as in Example 3, except that the heat sensitive layer composition solution-1 was changed to the following heat sensitive layer composition solution-17.

### Heat Sensitive Layer Composition Solution-17

(i) Infrared-absorbing dye (Cyanine dye): NK 5559 (manufactured by HAYASHIBARA CO., LTD., maximum absorption wavelength: 774 nm): 14.0 parts by mass
(ii) Dye that changes color by proton acceptance (Leuco dye having a maximum absorption wavelength of 580 nm when accepting protons): FB-1 (3′,6′-bis(diphenylamino)spiro[phthalide-3,9′-xanthene], manufactured by Fukui Yamada Chemical Co., Ltd.: 7.0 parts by mass
(iii) Proton-donating compound (polymer including active hydrogen-containing structural unit): Phenol formaldehyde novolac resin “Sumilite resin” (registered trademark) PR53195 (manufactured by Sumitomo Bakelite Co., Ltd.): 63.2 parts by mass
(iv) Organic complex compound: Titanium-n-butoxide bis (acetylacetonate): “Nācem” (registered trademark) titanium (manufactured by NIHON KAGAKU SANGYO CO., LTD., concentration: 73% by mass, containing n-butanol: 27% by mass as solvent): 15.8 parts by mass
(v) Tetrahydrofuran: 900 parts by mass

The resulting waterless planographic printing plate precursor was evaluated by the above method, thus obtaining very satisfactory image reproducibility, that is, the image reproduction ratio was 100% for 20 μm×20 μm dots, and 30% for 10 μm×20 μm dots. The peeling resistance of the ink repellent layer was very satisfactory, that is, the score was 5 points. The range of reflection densities ΔD_{C} measured by applying a cyan filter was 0.51, that is, very satisfactory results were obtained.

### Example 20

A planographic printing plate precursor was obtained in the same manner as in Example 3, except that the heat sensitive layer composition solution-1 was changed to the following heat sensitive layer composition solution-18.

### Heat Sensitive Layer Composition Solution-18

(i) Infrared-absorbing dye (Cyanine dye): NK 5559 (manufactured by HAYASHIBARA CO., LTD., maximum absorption wavelength: 774 nm): 14.0 parts by mass
(ii) Dye that changes color by proton acceptance (Leuco dye having a maximum absorption wavelength of 580 nm when accepting protons): FB-1 (3′,6′-bis(diphenylamino)spiro[phthalide-3,9′-xanthene], manufactured by Fukui Yamada Chemical Co., Ltd.: 11.0 parts by mass
(iii) Proton-donating compound (polymer including active hydrogen-containing structural unit): Phenol formaldehyde novolac resin “Sumilite resin” (registered trademark) PR53195 (manufactured by Sumitomo Bakelite Co., Ltd.): 60.0 parts by mass
(iv) Organic complex compound: Titanium-n-butoxide bis (acetylacetonate): “Nācem” (registered trademark) titanium (manufactured by NIHON KAGAKU SANGYO CO., LTD., concentration: 73% by mass, containing n-butanol: 27% by mass as solvent): 15.0 parts by mass
(v) Tetrahydrofuran: 900 parts by mass

The resulting waterless planographic printing plate precursor was evaluated by the above method, thus obtaining very satisfactory image reproducibility, that is, the image reproduction ratio was 100% for 20 μm×20 μm dots, and 30% for 10 μm×20 μm dots. The peeling resistance of the ink repellent layer was very satisfactory, that is, the score was 5 points. The range of reflection densities ΔD_{C} measured by applying a cyan filter was 0.55, that is, very satisfactory results were obtained.

### Example 21

A planographic printing plate precursor was obtained in the same manner as in Example 3, except that the heat sensitive layer composition solution-1 was changed to the following heat sensitive layer composition solution-19.

### Heat Sensitive Layer Composition Solution-19

(i) Infrared-absorbing dye (Cyanine dye): NK 5559 (manufactured by HAYASHIBARA CO., LTD., maximum absorption wavelength: 774 nm): 14.0 parts by mass
(ii) Dye that changes color by proton acceptance (Leuco dye having a maximum absorption wavelength of 580 nm when accepting protons): FB-1 (3′,6′-bis(diphenylamino)spiro[phthalide-3,9′-xanthene], manufactured by Fukui Yamada Chemical Co., Ltd.: 15.0 parts by mass
(iii) Proton-donating compound (polymer including active hydrogen-containing structural unit): Phenol formaldehyde novolac resin “Sumilite resin” (registered trademark)

PR53195 (manufactured by Sumitomo Bakelite Co., Ltd.): 56.8 parts by mass
(iv) Organic complex compound: Titanium-n-butoxide bis (acetylacetonate): “Nācem” (registered trademark) titanium (manufactured by NIHON KAGAKU SANGYO CO., LTD., concentration: 73% by mass, containing n-butanol: 27% by mass as solvent): 14.2 parts by mass
(v) Tetrahydrofuran: 900 parts by mass

The resulting waterless planographic printing plate precursor was evaluated by the above method, thus obtaining very satisfactory image reproducibility, that is, the image reproduction ratio was 100% for 20 μm×20 μm dots, and 30% for 10 μm×20 μm dots. The peeling resistance of the ink repellent layer was very satisfactory, that is, the score was 5 points. The range of reflection densities ΔD_{C} measured by applying a cyan filter was 0.59, that is, very satisfactory results were obtained.

### Example 22

A planographic printing plate precursor was obtained in the same manner as in Example 3, except that the heat sensitive layer composition solution-1 was changed to the following heat sensitive layer composition solution-20.

### Heat Sensitive Layer Composition Solution-20

(i) Infrared-absorbing dye (Cyanine dye): NK 5559 (manufactured by HAYASHIBARA CO., LTD., maximum absorption wavelength: 774 nm): 14.0 parts by mass
(ii) Dye that changes color by proton acceptance (Leuco dye having a maximum absorption wavelength of 580 nm when accepting protons): FB-1 (3′,6′-bis(diphenylamino)spiro[phthalide-3,9′-xanthene], manufactured by Fukui Yamada Chemical Co., Ltd.: 17.0 parts by mass
(iii) Proton-donating compound (polymer including active hydrogen-containing structural unit): Phenol formaldehyde novolac resin “Sumilite resin” (registered trademark) PR53195 (manufactured by Sumitomo Bakelite Co., Ltd.): 55.2 parts by mass
(iv) Organic complex compound: Titanium-n-butoxide bis (acetylacetonate): “Nācem” (registered trademark) titanium (manufactured by NIHON KAGAKU SANGYO CO., LTD., concentration: 73% by mass, containing n-butanol: 27% by mass as solvent): 13.8 parts by mass
(v) Tetrahydrofuran: 900 parts by mass

The resulting waterless planographic printing plate precursor was evaluated by the above method, thus obtaining very satisfactory image reproducibility, that is, the image reproduction ratio was 100% for 20 μm×20 μm dots, and 30% for 10 μm×20 μm dots. The peeling resistance of the ink repellent layer was satisfactory, that is, the score was 3 points. The range of reflection densities ΔD_{C} measured by applying a cyan filter was 0.59, that is, very satisfactory results were obtained.

### Comparative Example 1

The following organic layer composition liquid-2 was applied on a 0.24 mm thick degreased aluminum substrate (manufactured by Mitsubishi Aluminum Co., Ltd.) and then dried at 200° C. for 90 seconds to provide a 10.0 μm thick organic layer. The resulting substrate having an organic layer had a reflectance of less than 50% in the full wavelength range of 450 to 700 nm. The organic layer composition liquid-2 was obtained by stirring and mixing the following components at room temperature.

### Organic Layer Composition Liquid-2

(i) Epoxy phenolic resin “Kancoat” 90T-25-3094 (manufactured by KANSAI PAINT CO., LTD.): 100 parts by mass
(ii) Dimethylformamide: 900 parts by mass

Subsequently, the following heat sensitive layer composition solution-21 was applied on the organic layer and then heated and dried at 140° C. for 90 seconds to provide a 1.5 μm thick heat sensitive layer. The heat sensitive layer composition solution-21 was obtained by stirring and mixing the following components at room temperature.

### Heat Sensitive Layer Composition Solution-21

(i) Infrared-absorbing dye (Cyanine dye): “PROJET” 825 LDI (manufactured by Avecia): 11 parts by weight
(ii) Dye that changes color by proton acceptance (Leuco Dye): “Crystal Violet Lactone” (3, 3-bis (p-dimethylaminophenyl)-6-dimethylaminophthalide, manufactured by Yamamoto Chemicals Inc.): 5 parts by mass
(iii) Proton-donating compound (polymer including active hydrogen-containing structural unit): Phenol formaldehyde novolac resin “Sumilite resin” (registered trademark) PR53195 (manufactured by Sumitomo Bakelite Co., Ltd.): 67.2 parts by mass
(iv) Organic complex compound: Titanium-n-butoxide bis (acetylacetonate): “Nācem” (registered trademark) titanium (manufactured by NIHON KAGAKU SANGYO CO., LTD., concentration: 73% by mass, containing n-butanol: 27% by mass as solvent): 16.8 parts by mass
(v) Tetrahydrofuran: 900 parts by mass

Subsequently, the ink repellent layer (silicone rubber layer) composition solution prepared immediately before application was applied on the heat sensitive layer and then heated at 140° C. for 80 seconds to provide an ink repellent layer with an average film thickness of 2.5 μm, thus obtaining a waterless planographic printing plate precursor.

The resulting waterless planographic printing plate precursor was evaluated by the above method, and as a result, the peeling resistance of the ink repellent layer was very satisfactory, that is, the score was 5 points, but the image reproduction ratio was insufficient, that is, 60% for 20 μm×20 μm dots. Since the range of reflection densities ΔD_{C} measured by applying a cyan filter was as low as 0.15, information could not be read by the machine, thus failing to be put to practical use.

### Comparative Example 2

In the same manner in Comparative Example 1, except that, in (I-2) the step of removing the ink repellent layer of the image area of the exposed waterless planographic printing plate precursor, “NP-1” (manufactured by Toray Industries Inc., treatment liquid for waterless planographic negative type) was additionally charged in the pre-treatment tank of the automatic developing machine, and then the resulting waterless planographic printing plate precursor was subjected to “chemical development” and then evaluated.

The resulting waterless planographic printing plate precursor was evaluated by the above method, thus obtaining practically applicable results, that is, the image reproduction ratio was 90% for 20 μm×20 μm dots, but the peeling resistance of the ink repellent layer was poor, that is, the score was 0 point because chemical development of dissolving the heat sensitive layer was performed. Even if the chemical development was performed, the range of reflection densities Δd_{C} measured by applying a cyan filter was as low as 0.20, so that information could be read by the machine, thus failing to be put to practical use.

### Comparative Example 3

A planographic printing plate precursor was obtained in the same manner as in Example 3, except that the heat sensitive layer composition solution-3 was changed to the following heat sensitive layer composition solution-22.

### Heat Sensitive Layer Composition Solution-22

(i) Infrared-absorbing dye (Cyanine dye): NK 5559 (manufactured by HAYASHIBARA CO., LTD., maximum absorption wavelength: 774 nm): 12.0 parts by mass
(ii) Proton-donating compound (polymer including active hydrogen-containing structural unit): Phenol formaldehyde novolac resin “Sumilite resin” (registered trademark) PR53195 (manufactured by Sumitomo Bakelite Co., Ltd.): 70.4 parts by mass
(iii) Organic complex compound: Titanium-n-butoxide bis (acetylacetonate): “Nācem” (registered trademark) titanium (manufactured by NIHON KAGAKU SANGYO CO., LTD., concentration: 73% by mass, containing n-butanol:27% by mass as solvent): 17.6 parts by mass
(iv) Tetrahydrofuran: 900 parts by mass

The resulting waterless planographic printing plate precursor was evaluated by the above method, thus obtaining satisfactory image reproducibility, that is, the image reproduction ratio was 100% for 20 μm×20 μm dots, and 10% for 10 μm×20 μm dots. The peeling resistance of the ink repellent layer was very satisfactory, that is, the score was 5 points. However, since a dye that changes color by proton acceptance is not contained, the range of reflection densities ΔD_{C} measured by applying a cyan filter was as low as 0.03, so that it was difficult to visually recognized, thus failing to be put to practical use.

The min configuration and evaluation results of the respective Example and Comparative Example are shown in Tables 1 and 2.

TABLE 1

| | Heat sensitive layer | | | | | | | | |
|---|---|---|---|---|---|---|---|---|---|
| | (a) Infrared- | | (b) Dye that changes color | | | | | Substrate | |
| | absorbing dye | | by proton acceptance | | | | | White color | |
| | | Content | | | Content | | | layer/white | |
| | | (% by | | | (% by | (c) Proton-donating dye | | color | Whitening |
| | Name | mass ) | Type | Name | mass) | Type | Name | surface | method |
| Example 1 | NK5559 | 11.0 | Azo | Metanil | 5.0 | Acidic compound | p-Toluenesulfonic | White color | Roughening |
| | | | compound | Yellow | | | acid | surface | treatment |
| Example 2 | NK5559 | 11.0 | Azo | Metanil | 5.0 | Acidic compound | p-Toluenesulfonic | White color | White color |
| | | | compound | Yellow | | | acid | surface | PET |
| Example 3 | NK5559 | 11.0 | Azo | Metanil | 5.0 | Acidic compound | p-Toluenesulfonic | White color | Organic layer |
| | | | compound | Yellow | | | acid | layer | |
| Example 4 | NK5559 | 12.0 | Azo | Metanil | 5.0 | Acidic compound | p-Toluenesulfonic | White color | Organic layer |
| | | | compound | Yellow | | | acid | layer | |
| Example 5 | NK5559 | 14.0 | Azo | Metanil | 5.0 | Acidic compound | p-Toluenesulfonic | White color | Organic layer |
| | | | compound | Yellow | | | acid | layer | |
| Example 6 | NK5559 | 18.0 | Azo | Metanil | 5.0 | Acidic compound | p-Toluenesulfonic | White color | Organic layer |
| | | | compound | Yellow | | | acid | layer | |
| Example 7 | NK5559 | 20.0 | Azo | Metanil | 5.0 | Acidic compound | p-Toluenesulfonic | White color | Organic layer |
| | | | compound | Yellow | | | acid | layer | |
| Example 8 | NK5559 | 25.0 | Azo | Metanil | 5.0 | Acidic compound | p-Toluenesulfonic | White color | Organic layer |
| | | | compound | Yellow | | | acid | layer | |
| Example 9 | NK5559 | 14.0 | Leuco dye | RED 520 | 5.0 | Acidic compound | p-Toluenesulfonic | White color | Organic layer |
| | | | | | | | acid | layer | |
| Example 10 | NK5559 | 14.0 | Leuco dye | Blue 203 | 5.0 | Acidic compound | p-Toluenesulfonic | White color | Organic layer |
| | | | | | | | acid | layer | |
| Example 11 | NK5559 | 14.0 | Leuco dye | Blue 203 | 5.0 | Active hydrogen- | Acrylic resin | White color | Organic layer |
| | | | | | | containing polymer | | layer | |
| Example 12 | NK5559 | 14.0 | Leuco dye | Blue 203 | 5.0 | Active hydrogen- | Novolac resin | White color | Organic layer |
| | | | | | | containing polymer | | layer | |
| Example 13 | NK5559 | 11.0 | Leuco dye | FB-1 | 5.0 | Active hydrogen- | Novolac resin | White color | Organic layer |
| | | | | | | containing polymer | | layer | |
| Example 14 | NK5559 | 12.0 | Leuco dye | FB-1 | 5.0 | Active hydrogen- | Novolac resin | White color | Organic layer |
| | | | | | | containing polymer | | layer | |
| Example 15 | NK5559 | 18.0 | Leuco dye | FB-1 | 5.0 | Active hydrogen- | Novolac resin | White color | Organic layer |
| | | | | | | containing polymer | | layer | |
| Example 16 | NK5559 | 20.0 | Leuco dye | FB-1 | 5.0 | Active hydrogen- | Novolac resin | White color | Organic layer |
| | | | | | | containing polymer | | layer | |
| Example 17 | NK5559 | 25.0 | Leuco dye | FB-1 | 5.0 | Active hydrogen- | Novolac resin | White color | Organic layer |
| | | | | | | containing polymer | | layer | |
| Example 18 | NK5559 | 14.0 | Leuco dye | FB-1 | 5.0 | Active hydrogen- | Novolac resin | White color | Organic layer |
| | | | | | | containing polymer | | layer | |
| Example 19 | NK5559 | 14.0 | Leuco dye | FB-1 | 7.0 | Active hydrogen- | Novolac resin | White color | Organic layer |
| | | | | | | containing polymer | | layer | |
| Example 20 | NK5559 | 14.0 | Leuco dye | FB-1 | 11.0 | Active hydrogen- | Novolac resin | White color | Organic layer |
| | | | | | | containing polymer | | layer | |
| Example 21 | NK5559 | 14.0 | Leuco dye | FB-1 | 15.0 | Active hydrogen- | Novolac resin | White color | Organic layer |
| | | | | | | containing polymer | | layer | |
| Example 22 | NK5559 | 14.0 | Leuco dye | FB-1 | 17.0 | Active hydrogen- | Novolac resin | White color | Organic layer |
| | | | | | | containing polymer | | layer | |
| Comparative | “PROJET” | 11 | Leuco dye | Crystal | 5 | Active hydrogen- | Novolac resin | None | — |
| Example 1 | 825LDI | | | Violet | | containing polymer | | | |
| | | | | Lactone | | | | | |
| Comparative | “PROJET” | 11 | Leuco dye | Crystal | 5 | Active hydrogen- | Novolac resin | None | — |
| Example 2 | 825LDI | | | Violet | | containing polymer | | | |
| | | | | Lactone | | | | | |
| Comparative | NK5559 | 12 | None | — | — | Active hydrogen- | Novolac | White color | Organic layer |
| Example 3 | | | | | | containing polymer | resin | layer | |

TABLE 2

| | | Evaluation results | | | |
|---|---|---|---|---|---|
| | | Image reproducibility | | Peeling | Contrast |
| | | 10 × | 20 × | resis- | between |
| | Development | 20 μm | 20 μm | tance | image |
| | step | dot Image | dot Image | of ink | area |
| | Pre- | reproduc- | reproduc- | repel- | and non- |
| | treatment | tion | tion | lent | image |
| | liquid | ratio (%) | ratio (%) | layer | area |
| Example 1 | None | 0 | 90 | 3 | 0.30 |
| Example 2 | None | 0 | 90 | 3 | 0.31 |
| Example 3 | None | 0 | 90 | 3 | 0.33 |
| Example 4 | None | 10 | 100 | 3 | 0.33 |
| Example 5 | None | 30 | 100 | 3 | 0.35 |
| Example 6 | None | 55 | 100 | 3 | 0.40 |
| Example 7 | None | 70 | 100 | 2 | 0.42 |
| Example 8 | None | 80 | 100 | 1 | 0.42 |
| Example 9 | None | 30 | 100 | 3 | 0.45 |
| Example 10 | None | 30 | 100 | 3 | 0.48 |
| Example 11 | None | 30 | 100 | 4 | 0.48 |
| Example 12 | None | 30 | 100 | 5 | 0.48 |
| Example 13 | None | 0 | 90 | 5 | 0.43 |
| Example 14 | None | 10 | 100 | 5 | 0.43 |
| Example 15 | None | 55 | 100 | 5 | 0.50 |
| Example 16 | None | 70 | 100 | 4 | 0.52 |
| Example 17 | None | 80 | 100 | 3 | 0.52 |
| Example 18 | None | 30 | 100 | 5 | 0.48 |
| Example 19 | None | 30 | 100 | 5 | 0.51 |
| Example 20 | None | 30 | 100 | 5 | 0.55 |
| Example 21 | None | 30 | 100 | 5 | 0.59 |
| Example 22 | None | 30 | 100 | 3 | 0.59 |
| Comparative | None | 0 | 60 | 5 | 0.15 |
| Example 1 | | | | | |
| Comparative | Yes | 0 | 90 | 0 | 0.20 |
| Example 2 | | | | | |
| Comparative | None | 10 | 100 | 5 | 0.03 |
| Example 3 | | | | | |

1. A waterless planographic printing plate precursor comprising at least a substrate, a heat sensitive layer and an ink repellent layer in this order, wherein the substrate has a white color layer or a white color surface, and wherein the heat sensitive layer comprises at least (a) an infrared-absorbing dye having a maximum absorption wavelength of 700 to 1,000 nm, (b) a dye that changes color by proton acceptance, and (c) a proton-donating compound.

2. The waterless planographic printing plate precursor according to claim 1, wherein the heat sensitive layer contains 12 to 20% by mass of the infrared-absorbing dye (a) having a maximum absorption wavelength of 700 to 1,000 nm.

3. The waterless planographic printing plate precursor of claim 1, comprising a leuco dye as the dye that changes color by proton acceptance (b).

4. The waterless planographic printing plate precursor according to claim 1, wherein the dye that changes color by proton acceptance (b) has a maximum absorption wavelength in the range of 500 to 650 nm when accepting protons.

5. The waterless planographic printing plate precursor according to claim 1, comprising, as the proton-donating compound (c), a polymer including an active hydrogen-containing structural unit.

6. The waterless planographic printing plate precursor according to claim 1, comprising, as the proton-donating compound (c), a novolac resin.

7. A waterless planographic printing plate precursor comprising at least a substrate, a heat sensitive layer and an ink repellent layer in this order, wherein when at least a part of the waterless planographic printing plate precursor is irradiated with 100 mJ/cm² of infrared rays, a range of reflection densities ΔD_{C} between an exposed area and a non-exposed area measured from the ink repellent layer side using a cyan-filtered spectrophotometer is 0.30 or more.

8. A method for producing a waterless planographic printing plate, which comprises (1) the step of imagewise exposing the waterless planographic printing plate precursor according to claim 1 to form an image area and a non-image area.

9. The method for producing a waterless planographic printing plate according to claim 8, further comprising, after (1) the step of imagewise exposing to form an image area and a non-image area, (2) the step of removing an ink repellent layer of the image area of the exposed waterless planographic printing plate precursor.

10. The method for producing a waterless planographic printing plate according to claim 9, wherein an organic solvent is not used in (2) the step of removing an ink repellent layer of the image area of the exposed waterless planographic printing plate precursor.

11. The method for producing a waterless planographic printing plate according to claim 8, wherein a range of reflection densities ΔD_{C} between an exposed area and a non-exposed area measured from the ink repellent layer side using a cyan-filtered spectrophotometer of an image area and a non-image area of the waterless planographic printing plate, after (1) the step of imagewise exposing to form an image area and a non-image area is 0.30 or more.

12. A method for sorting a waterless planographic printing plate, which comprises discriminating an image pattern formed on the waterless planographic printing plate obtained by the producing method according to claim 8 by a machine, followed by rearrangement and/or classification.

13. A method for producing a printed material, which comprises the steps of adhering an ink on the surface of the waterless planographic printing plate obtained by the producing method of claim 8, and transferring the ink directly or via a blanket to a printable medium.

14. A method for producing a printed material which comprises the steps of
adhering an ink on the surface of the waterless planographic printing plate obtained by imagewise exposing a waterless planographic printing plate precursor that comprises at least a substrate, a heat sensitive layer and an ink repellent layer in this order, wherein the substrate has a white color layer or a white color surface, and wherein the heat sensitive layer comprises at least (a) an infrared-absorbing dye having a maximum absorption wavelength of 700 to 1,000 nm, (b) a dye that changes color by proton acceptance, and (c) a proton-donating compound to form an image area and a non-image area, and
transferring the ink directly or via a blanket to a printable medium, wherein the waterless planographic printing plate sorted by the method according to claim 12 is used as the waterless planographic printing plate.
